(19) United States
(12) Patent Application Publication
(10) Pub. No.: US 2026/0080919 A1
(43) Pub. Date: Mar. 19, 2026

(54) SEMICONDUCTOR MEMORY DEVICE

(71) Applicant: KIOXIA CORPORATION, Tokyo (JP)

(72) Inventor: Akira MINO, Yokkaichi Mie (JP)

(73) Assignee: KIOXIA CORPORATION, Tokyo (JP)

(21) Appl. No.: 19/079,602

(22) Filed: Mar. 14, 2025

(30) Foreign Application Priority Data
Sep. 18, 2024 (JP) 2024-161413

(51) Int. Cl. G11C 5/06; G11C 16/04; H10B 43/10; H10B 43/27

(52) U.S. Cl. CPC G11C 5/063; G11C 16/0483; H10B 43/10; H10B 43/27

(57) ABSTRACT

A semiconductor memory device comprises: conductive layers stacked in a stacking direction; memory cells connected to the conductive layers; a first contact electrode extending in the stacking direction and connected to one of the conductive layers; and a second contact electrode connected to an end portion in the stacking direction of the first contact electrode. The first contact electrode comprises: a first conductive member extending in the stacking direction; an insulating column which extends in the stacking direction and has an outer peripheral surface covered by the first conductive member; and a second conductive member provided in the end portion on a second contact electrode side in the stacking direction of the first contact electrode, has an outer peripheral surface contacting the first conductive member, and has a surface on the second contact electrode side in the stacking direction contacting the second contact electrode.

### CROSS-REFERENCE TO RELATED APPLICATIONS

This application is based upon and claims the benefit of Japanese Patent Application No. 2024-161413, filed on Sep. 18, 2024, the entire contents of which are incorporated herein by reference.

### BACKGROUND

### Field

The present embodiments relate to semiconductor memory devices.

### Description of the Related Art

There is known a semiconductor memory device comprising: a plurality of conductive layers stacked in a stacking direction; a plurality of memory cells arranged in the stacking direction and connected to the plurality of conductive layers; and a contact electrode extending in the stacking direction and connected to one of the plurality of conductive layers.

### BRIEF DESCRIPTION OF THE DRAWINGS

FIG. 1 is a schematic circuit diagram of a semiconductor memory device according to a first embodiment;

FIG. 2 is a schematic plan view of a memory die MD;

FIG. 3 is a schematic plan view of a semiconductor column region R_{MH};

FIG. 4 is a schematic cross-sectional view of the semiconductor column region R_{MH};

FIG. 5 is a schematic cross-sectional view of the semiconductor column region R_{MH};

FIG. 6 is a schematic cross-sectional view of the semiconductor column region R_{MH};

FIG. 7 is a schematic plan view for explaining a hook-up region R_{HU};

FIG. 8 is a schematic plan view for explaining the hook-up region R_{HU};

FIG. 9 is a schematic cross-sectional view of the hook-up region R_{HU};

FIG. 10 is a schematic cross-sectional view of the hook-up region R_{HU};

FIG. 11 is a schematic cross-sectional view for explaining a method of manufacturing the semiconductor memory device according to the first embodiment;

FIG. 12 is a schematic cross-sectional view for explaining same method of manufacturing;

FIG. 13 is a schematic cross-sectional view for explaining same method of manufacturing;

FIG. 14 is a schematic cross-sectional view for explaining same method of manufacturing;

FIG. 15 is a schematic cross-sectional view for explaining same method of manufacturing;

FIG. 16 is a schematic cross-sectional view for explaining same method of manufacturing;

FIG. 17 is a schematic cross-sectional view for explaining same method of manufacturing;

FIG. 18 is a schematic cross-sectional view for explaining same method of manufacturing;

FIG. 19 is a schematic cross-sectional view for explaining same method of manufacturing;

FIG. 20 is a schematic cross-sectional view for explaining same method of manufacturing;

FIG. 21 is a schematic cross-sectional view for explaining same method of manufacturing;

FIG. 22 is a schematic cross-sectional view for explaining same method of manufacturing;

FIG. 23 is a schematic cross-sectional view for explaining same method of manufacturing;

FIG. 24 is a schematic cross-sectional view for explaining same method of manufacturing;

FIG. 25 is a schematic cross-sectional view for explaining same method of manufacturing;

FIG. 26 is a schematic cross-sectional view for explaining same method of manufacturing;

FIG. 27 is a schematic cross-sectional view for explaining same method of manufacturing;

FIG. 28 is a schematic cross-sectional view for explaining same method of manufacturing;

FIG. 29 is a schematic cross-sectional view for explaining same method of manufacturing;

FIG. 30 is a schematic cross-sectional view for explaining same method of manufacturing;

FIG. 31 is a schematic cross-sectional view for explaining same method of manufacturing;

FIG. 32 is a schematic cross-sectional view for explaining same method of manufacturing;

FIG. 33 is a schematic cross-sectional view for explaining same method of manufacturing;

FIG. 34 is a schematic cross-sectional view for explaining same method of manufacturing;

FIG. 35 is a schematic cross-sectional view for explaining same method of manufacturing;

FIG. 36 is a schematic cross-sectional view for explaining same method of manufacturing;

FIG. 37 is a schematic cross-sectional view for explaining same method of manufacturing;

FIG. 38 is a schematic cross-sectional view for explaining same method of manufacturing;

FIG. 39 is a schematic cross-sectional view for explaining same method of manufacturing;

FIG. 40 is a schematic cross-sectional view for explaining same method of manufacturing;

FIG. 41 is a schematic cross-sectional view for explaining same method of manufacturing;

FIG. 42 is a schematic cross-sectional view for explaining same method of manufacturing;

FIG. 43 is a schematic cross-sectional view for explaining same method of manufacturing;

FIG. 44 is a schematic cross-sectional view for explaining same method of manufacturing;

FIG. 45 is a schematic cross-sectional view for explaining same method of manufacturing;

FIG. 46 is a schematic cross-sectional view for explaining same method of manufacturing;

FIG. 47 is a schematic cross-sectional view for explaining same method of manufacturing;

FIG. 48 is a schematic cross-sectional view for explaining same method of manufacturing;

FIG. 49 is a schematic cross-sectional view for explaining same method of manufacturing;

FIG. 50 is a schematic cross-sectional view for explaining same method of manufacturing;

FIG. 51 is a schematic cross-sectional view for explaining same method of manufacturing;

FIG. 52 is a schematic cross-sectional view for explaining same method of manufacturing;

FIG. 53 is a schematic cross-sectional view for explaining same method of manufacturing;

FIG. 54 is a schematic cross-sectional view for explaining same method of manufacturing;

FIG. 55 is a schematic cross-sectional view for explaining same method of manufacturing;

FIG. 56 is a schematic cross-sectional view for explaining same method of manufacturing;

FIG. 57 is a schematic cross-sectional view for explaining same method of manufacturing;

FIG. 58 is a schematic cross-sectional view for explaining same method of manufacturing;

FIG. 59 is a schematic cross-sectional view for explaining same method of manufacturing;

FIG. 60 is a schematic cross-sectional view of a semiconductor memory device according to a second embodiment;

FIG. 61 is a schematic cross-sectional view of a semiconductor memory device according to a third embodiment;

FIG. 62 is a schematic cross-sectional view of a semiconductor memory device according to a fourth embodiment;

FIG. 63 is a schematic cross-sectional view of a semiconductor memory device according to a fifth embodiment;

FIG. 64 is a schematic cross-sectional view of a semiconductor memory device according to a sixth embodiment; and

FIG. 65 is a schematic cross-sectional view of a semiconductor memory device according to another embodiment.

### DETAILED DESCRIPTION

A semiconductor memory device according to one embodiment comprises: a plurality of conductive layers stacked in a stacking direction; a plurality of memory cells which are arranged in the stacking direction and are connected to the plurality of conductive layers; a first contact electrode which extends in the stacking direction and is connected to one of the plurality of conductive layers; and a second contact electrode which extends in the stacking direction and is connected to an end portion in the stacking direction of the first contact electrode. The first contact electrode comprises: a first conductive member extending in the stacking direction; an insulating column which extends in the stacking direction and has an outer peripheral surface covered by the first conductive member; and a second conductive member which is provided in the end portion on a second contact electrode side in the stacking direction of the first contact electrode, has an outer peripheral surface contacting the first conductive member, and has a surface on the second contact electrode side in the stacking direction contacting the second contact electrode.

Next, semiconductor memory devices according to embodiments will be described in detail with reference to the drawings. Note that the following embodiments are merely examples, and are not shown with the intention of limiting the present invention. Moreover, the following drawings are schematic, and, for convenience of description, a part of configurations, and so on, thereof will sometimes be omitted. Moreover, portions that are common to a plurality of embodiments will be assigned with the same symbols, and descriptions thereof sometimes omitted.

Moreover, when a “semiconductor memory device” is referred to in the present specification, it will sometimes mean a memory die, and will sometimes mean a memory system including a controller die, of the likes of a memory chip, a memory card, or an SSD (Solid State Drive). Furthermore, it will sometimes mean a configuration including a host computer, of the likes of a smartphone, a tablet terminal, or a personal computer.

Moreover, in the present specification, when a first configuration is said to be “electrically connected” to a second configuration, the first configuration may be connected to the second configuration directly, or the first configuration may be connected to the second configuration via the likes of a wiring, a semiconductor member, or a transistor. For example, in the case of three transistors having been connected in series, the first transistor is still “electrically connected” to the third transistor even when the second transistor is in an OFF state.

Moreover, in the present specification, a certain direction parallel to an upper surface of a substrate will be referred to as an X-direction, a direction parallel to the upper surface of the substrate and perpendicular to the X-direction will be referred to as a Y-direction, and a direction perpendicular to the upper surface of the substrate will be referred to as a Z-direction.

Moreover, in the present specification, a direction intersecting a surface of the substrate will sometimes be referred to as a stacking direction. Moreover, a direction along a certain plane intersecting the stacking direction will sometimes be referred to as a first direction, and a direction intersecting the first direction along this plane will sometimes be referred to as a second direction. The stacking direction may coincide with the Z-direction, but need not do so. Moreover, the first direction and the second direction may correspond to any of the X-direction and the Y-direction, but need not do so.

Moreover, in the present specification, expressions such as “above” or “below” will be defined with reference to the substrate. For example, an orientation of moving away from the substrate along the above-described Z-direction will be referred to as above, and an orientation of coming closer to the substrate along the Z-direction will be referred to as below. Moreover, when a lower surface or a lower end is referred to for a certain configuration, this will be assumed to mean a surface or end portion on a substrate side of this configuration, and when an upper surface or an upper end is referred to for a certain configuration, this will be assumed to mean a surface or end portion on an opposite side to the substrate of this configuration. Moreover, a surface intersecting the X-direction or the Y-direction will be referred to as a side surface, and so on.

Moreover, in the present specification, when the likes of a “width”, a “length”, or a “thickness” in a certain direction is referred to for a configuration, a member, and so on, this will sometimes mean a width, a length, or a thickness, and so on, in a cross section observed by the likes of SEM (Scanning Electron Microscopy) or TEM (Transmission Electron Microscopy), and so on.

### First Embodiment

### [Circuit Configuration]

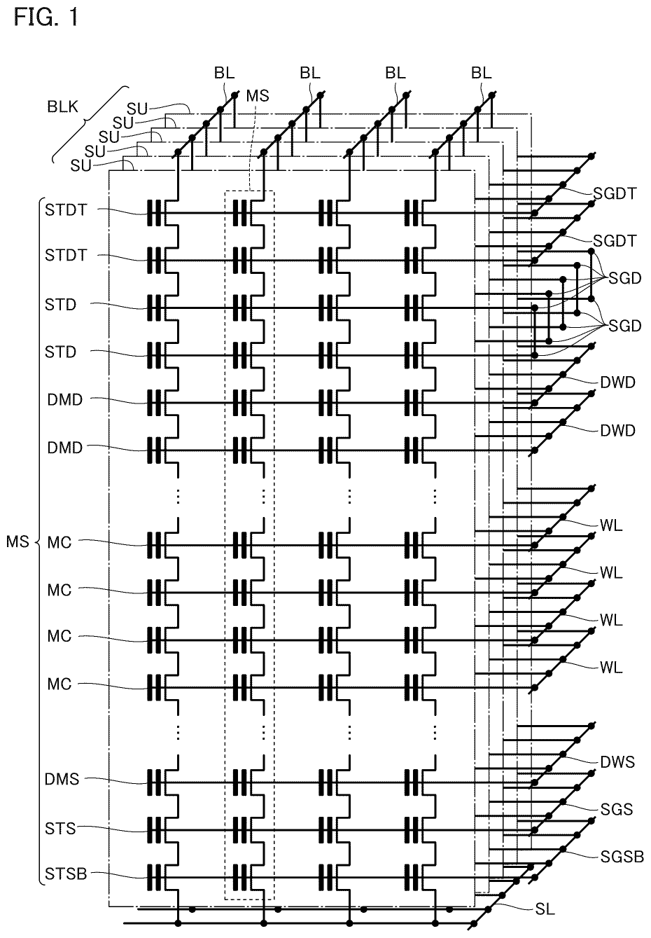

FIG. 1 is a schematic circuit diagram of a semiconductor memory device according to a first embodiment. The semiconductor memory device according to the present embodiment comprises a memory block BLK. The memory block BLK comprises a plurality of string units SU. These plurality of string units SU each comprise a plurality of memory strings MS. These plurality of memory strings MS have one ends each connected to a peripheral circuit via bit lines BL. Moreover, these plurality of memory strings MS have the other ends each connected to the peripheral circuit via a common source line SL.

The memory string MS comprises: drain side select transistors STDT, STD; one or a plurality of dummy memory cells DMD; a plurality of memory cells MC (memory transistors); one or a plurality of dummy memory cells DMS; and source side select transistors STS, STSB. The drain side select transistors STDT, STD, the one or the plurality of dummy memory cells DMD, the plurality of memory cells MC, the one or the plurality of dummy memory cells DMS, and the source side select transistors STS, STSB are connected in series between the bit line BL and the source line SL. Hereafter, the drain side select transistors STDT, STD and the source side select transistor STS, STSB will sometimes simply be referred to as select transistors STDT, STD, STS, STSB.

The memory cell MC is a field effect type transistor. The memory cell MC comprises a part of a semiconductor column, comprises a gate insulating film, and comprises a gate electrode. The part of the semiconductor column functions as a channel region. The gate insulating film includes an electric charge accumulating film. A threshold voltage of the memory cell MC changes according to an amount of charge in the electric charge accumulating film. The memory cell MC stores 1 bit or a plurality of bits of data. Note that the respective gate electrodes of the plurality of memory cells MC corresponding to one memory string MS are connected with word lines WL. These respective word lines WL are commonly connected to all of the memory strings MS in one memory block BLK.

The dummy memory cells DMD, DMS are basically configured similarly to the memory cell MC. However, the dummy memory cells DMD, DMS do not have data stored therein. Note that the respective gate electrodes of the one or the plurality of dummy memory cells DMD corresponding to one memory string MS are connected with dummy word lines DWD. These respective dummy word lines DWD are commonly connected to all of the memory strings MS in one memory block BLK. Similarly, the respective gate electrodes of the one or the plurality of dummy memory cells DMS corresponding to one memory string MS are connected with dummy word lines DWS. These respective dummy word lines DWS are commonly connected to all of the memory strings MS in one memory block BLK.

The select transistors STDT, STD, STS, STSB are each a field effect type transistor. The select transistors STDT, STD, STS, STSB each comprise a part of a semiconductor column, each comprise a gate insulating film, and each comprise a gate electrode. The part of the semiconductor column functions as a channel region. The gate electrodes of the select transistors STDT, STD, STS, STSB are respectively connected with select gate lines SGDT, SGD, SGS, SGSB. The drain side select gate line SGDT is commonly connected to all of the memory strings MS in one memory block BLK. The drain side select gate line SGD is commonly connected to all of the memory strings MS in one string unit SU. The source side select gate line SGS is commonly connected to all of the memory strings MS in one memory block BLK. The source side select gate line SGSB is commonly connected to all of the memory strings MS in one memory block BLK.

### [Structure]

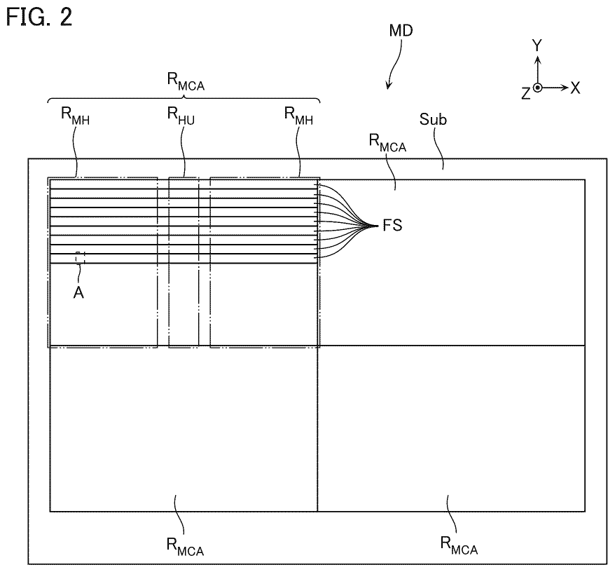

FIG. 2 is a schematic plan view of a memory die MD. The memory die MD comprises a semiconductor substrate Sub. In the example illustrated, the semiconductor substrate Sub is provided with four memory cell array regions R_{MCA} arranged in the X-direction and the Y-direction.

The memory cell array region R_{MCA} comprises a plurality of finger structures FS arranged in the Y-direction. In the present embodiment, one finger structure FS functions as one memory block BLK (FIG. 1). However, a plurality of the finger structures FS may function as one memory block BLK.

Moreover, the memory cell array regions R_{MCA} each comprise: two semiconductor column regions R_{MH} arranged in the X-direction; and a hook-up region R_{HU} provided between these two semiconductor column regions R_{MH}. Structure in these regions will be explained in order below.

### [Structure in Semiconductor Column Region R_{MH}]

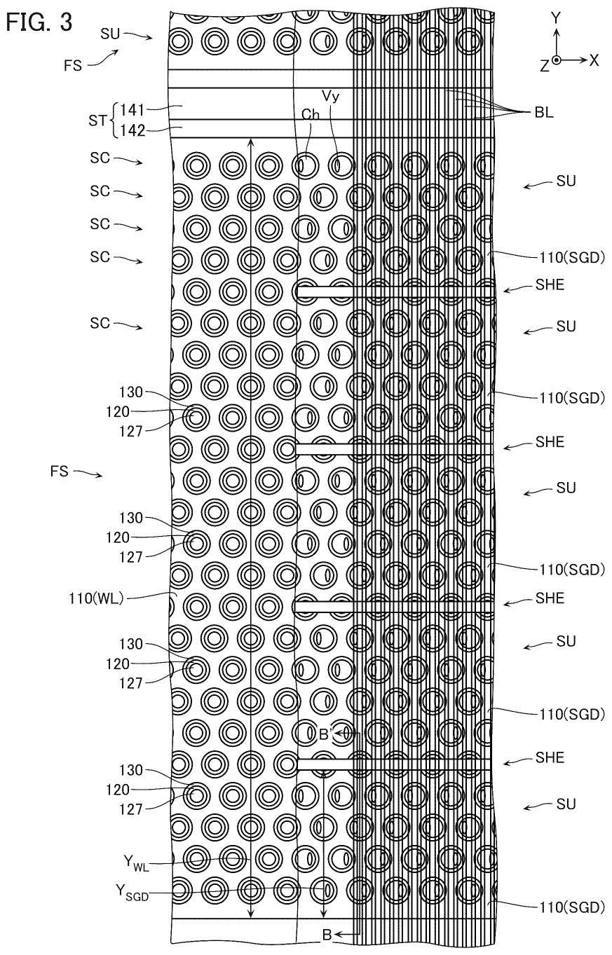

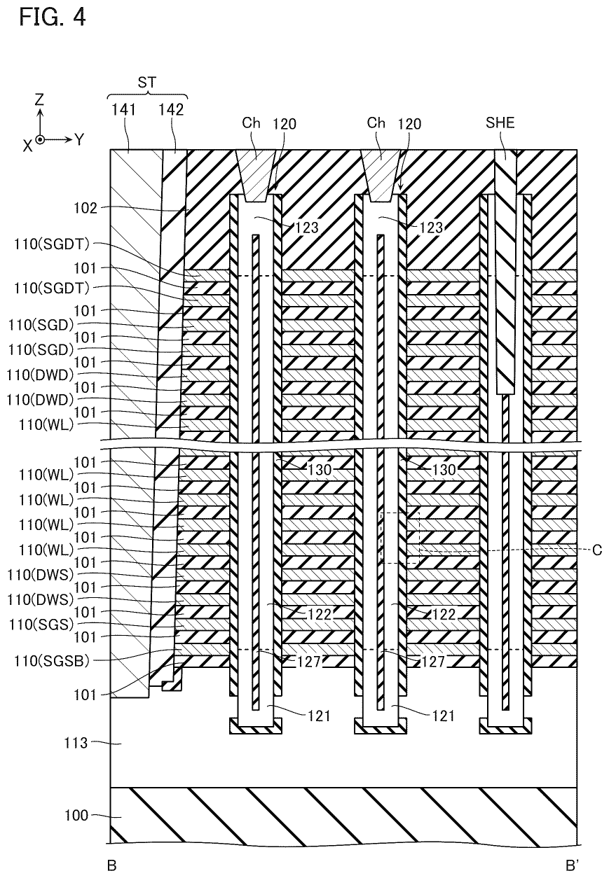

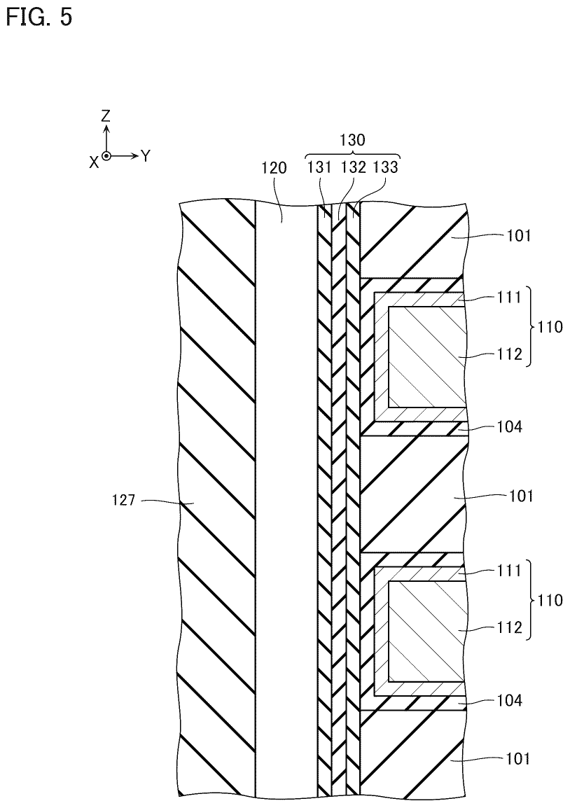

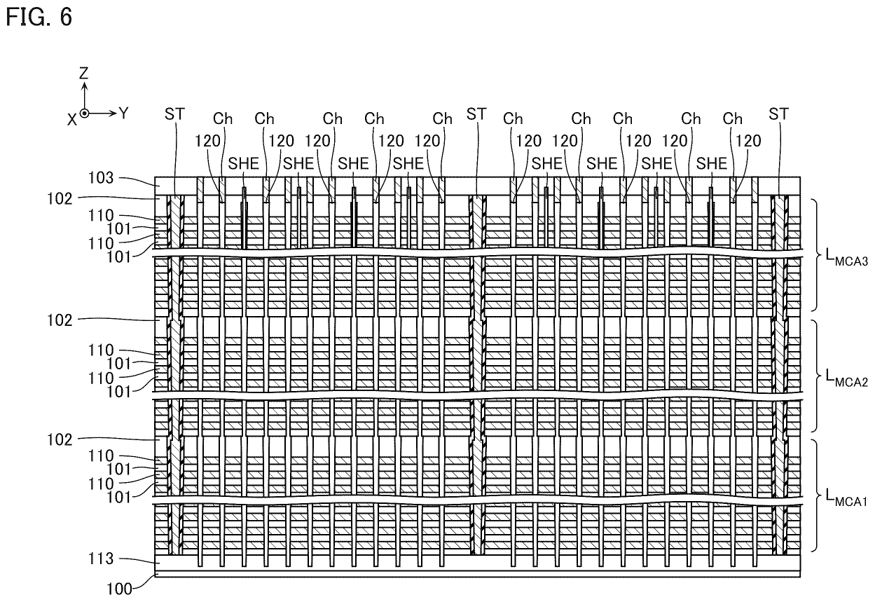

First, structure in the semiconductor column region R_{MH} will be described with reference to FIGS. 3 to 6. FIG. 3, which is a schematic plan view of the semiconductor column region R_{MH}, shows enlarged the portion indicated by A in FIG. 2. A certain region of FIG. 3 shows an XY cross section at a height position corresponding to a later-mentioned conductive layer 110(WL). The remaining region of FIG. 3 shows a view of the portion indicated by A in FIG. 2 viewed from above. Moreover, in this remaining region, later-mentioned insulating layers 102, 103 and a later-mentioned conductive layer 110(SGDT) are omitted. Moreover, in a part of this remaining region, the bit lines BL are omitted. FIG. 4, which is a schematic cross-sectional view of the semiconductor column region R_{MH}, shows a cross section of the structure shown in FIG. 3 taken along the line B-B′ and viewed along a direction of the arrows. FIG. 5, which is a schematic cross-sectional view of the semiconductor column region R_{MH}, shows enlarged the portion indicated by C in FIG. 4. Note that although FIG. 5 shows a YZ cross section, a similar structure to in FIG. 5 will be observed, even when a cross section other than a YZ cross section along a central axis of a later-mentioned semiconductor column 120 (for example, an XZ cross section) is observed. FIG. 6 is a schematic cross-sectional view of the semiconductor column region R_{MH}.

As shown in FIG. 3, for example, the finger structure FS comprises five of the string units SU arranged in the Y-direction. An inter-finger structure ST is provided between two finger structures FS adjacent in the Y-direction. Moreover, an inter-string unit insulating member SHE of the likes of silicon oxide (SiO₂) is provided between two string units SU adjacent in the Y-direction. Note that the finger structure FS may comprise two to four string units SU, or may comprises six or more string units SU.

As shown in FIG. 6, the finger structure FS comprises three memory cell array layers L_{MCA1}, L_{MCA2}, L_{MCA3} arranged in the Z-direction. The memory cell array layers L_{MCA1}, L_{MCA2}, L_{MCA3} each comprise a plurality of conductive layers 110 arranged in the Z-direction. A conductive layer 113 is provided below the memory cell array layer L_{MCA1}. In addition, the finger structure FS comprises a plurality of semiconductor columns 120 extending in the Z-direction over these three memory cell array layers L_{MCA1}, L_{MCA2}, L_{MCA3}. Moreover, as shown in FIG. 4, a gate insulating film 130 is provided between each of the plurality of conductive layers 110 and the plurality of semiconductor columns 120.

The conductive layer 110 comprises a substantially plate-like shape extending in the X-direction. The conductive layer 110 may include the likes of a stacked film having stacked therein a barrier conductive film 111 of the likes of titanium nitride (TiN) and a metal film 112 of the likes of tungsten (W), as shown in FIG. 5, for example, or may include the likes of polycrystalline silicon including an impurity such as phosphorus (P) or boron (B). Moreover, upper and lower surfaces, and a surface facing the semiconductor column 120, of the conductive layer 110 may be provided with a high-dielectric-constant insulating film 104. The high-dielectric-constant insulating film 104 may include a metal oxide film of the likes of aluminum oxide (AlO), hafnium oxide (HfO), or zirconium oxide (ZrO), for example.

As shown in FIG. 6, the memory cell array layers L_{MCA1}, L_{MCA2}, L_{MCA3} each comprise: a plurality of the conductive layers 110 and a plurality of insulating layers 101 arranged alternately in the Z-direction; and an insulating layer 102 provided above these pluralities of conductive layers 110 and insulating layers 101. Moreover, an insulating layer 103 is provided above the memory cell array layer L_{MCA3}. The insulating layers 101, 102, 103 include the likes of silicon oxide (SiO₂). For example, thickness in the Z-direction of the insulating layers 102, 103 is greater than thickness in the Z-direction of the insulating layer 101.

A plurality of the conductive layers 110 function as the word line WL (FIG. 1) and as the gate electrodes of the plurality of memory cells MC (FIG. 1) connected to this word line WL. In the following description, as shown in FIG. 4, for example, such a conductive layer 110 will sometimes be referred to as a conductive layer 110(WL). The plurality of conductive layers 110(WL) are each electrically independent every finger structure FS. Side surfaces on a positive side in the Y-direction and a negative side in the Y-direction of the conductive layer 110(WL) are electrically insulated from configurations in another finger structure FS, via the inter-finger structure ST.

One or a plurality of conductive layers 110 located below the plurality of conductive layers 110(WL) function as the dummy word line DWS (FIG. 1) and as the gate electrodes of the plurality of dummy memory cells DMS (FIG. 1) connected to this dummy word line DWS. In the following description, such a conductive layer 110 will sometimes be referred to as a conductive layer 110(DWS). The conductive layer 110(DWS) is configured similarly to the conductive layer 110(WL).

One or a plurality of conductive layers 110 located below the one or the plurality of conductive layers 110(DWS) function as the source side select gate line SGS (FIG. 1) and as the gate electrodes of the plurality of source side select transistors STS (FIG. 1) connected to this source side select gate line SGS. In the following description, such a conductive layer 110 will sometimes be referred to as a conductive layer 110(SGS). The conductive layer 110(SGS) is configured similarly to the conductive layer 110(WL).

One or a plurality of conductive layers 110 located below the one or the plurality of conductive layers 110(SGS) function as the source side select gate line SGSB (FIG. 1) and as the gate electrodes of the plurality of source side select transistors STSB (FIG. 1) connected to this source side select gate line SGSB. In the following description, such a conductive layer 110 will sometimes be referred to as a conductive layer 110(SGSB). The conductive layer 110(SGSB) is configured similarly to the conductive layer 110(WL).

One or a plurality of conductive layers 110 located above the plurality of conductive layers 110(WL) function as the dummy word line DWD (FIG. 1) and as the gate electrodes of the plurality of dummy memory cells DMD (FIG. 1) connected to this dummy word line DWD. In the following description, such a conductive layer 110 will sometimes be referred to as a conductive layer 110(DWD). A part of the conductive layers 110(DWD) may be configured similarly to the conductive layer 110(WL). Another part of the conductive layers 110(DWD) provided above the part of the conductive layers 110(DWD) may be basically configured similarly to a later-mentioned conductive layer 110(SGD). However, the five conductive layers 110(DWD) arranged in the Y-direction at a certain height position in one finger structure FS are electrically connected with each other.

The one or a plurality of conductive layers 110 located above the one or the plurality of conductive layers 110(DWD) function as the drain side select gate line SGD (FIG. 1) and as the gate electrodes of the plurality of drain side select transistors STD (FIG. 1) connected to this drain side select gate line SGD. In the following description, such a conductive layer 110 will sometimes be referred to as a conductive layer 110(SGD).

As shown in FIG. 3, the finger structure FS includes five conductive layers 110(SGD) arranged in the Y-direction, via the inter-string unit insulating members SHE, at a certain height position. A width Y_{SGD} in the Y-direction of the conductive layer 110(SGD) is less than a width Y_{WL} in the Y-direction of the conductive layer 110(WL). These five conductive layers 110(SGD) are each electrically independent every string unit SU. In each finger structure FS, the conductive layers 110(SGD) corresponding to the 1^{st} and 5^{th} string units SU counting from one side in the Y-direction (for example, a negative side in the Y-direction) are electrically insulated from configurations in another finger structure FS, via the inter-finger structure ST provided between the finger structures FS. Moreover, in each finger structure FS, two conductive layers 110(SGD) adjacent in the Y-direction are electrically insulated via the inter-string unit insulating member SHE.

One or a plurality of conductive layers 110 located above the conductive layer 110(SGD) function as the drain side select gate line SGDT (FIG. 1) and as the gate electrodes of the plurality of drain side select transistors STDT (FIG. 1) connected to this drain side select gate line SGDT. In the following description, such a conductive layer 110 will sometimes be referred to as a conductive layer 110(SGDT). The conductive layer 110(SGDT) is basically configured similarly to the conductive layer 110(SGD). However, the five conductive layers 110(SGDT) arranged in the Y-direction at a certain height position in one finger structure FS are electrically connected with each other.

The conductive layer 113 (FIG. 4) may include the likes of polycrystalline silicon including an impurity such as phosphorus (P) or boron (B), for example. Moreover, a lower surface of the conductive layer 113 may be provided with a metal such as tungsten (W), a conductive layer of the likes of tungsten silicide, or another conductive layer. The insulating layer 101 of the likes of silicon oxide (SiO₂) is provided between the conductive layer 113 and the conductive layer 110. Moreover, an insulating layer 100 of the likes of silicon oxide (SiO₂) is provided below the conductive layer 113.

The conductive layer 113 functions as a part of the source line SL (FIG. 1). The conductive layer 113 is commonly provided for all of the finger structures FS included in the memory cell array region R_{MCA} (FIG. 3), for example.

As shown in FIG. 3, for example, the semiconductor columns 120 are arranged in a certain pattern in the X-direction and the Y-direction. For example, the finger structure FS comprises 24 semiconductor column rows SC provided from one side in the Y-direction to the other side in the Y-direction. These 24 semiconductor column rows SC each comprise a plurality of the semiconductor columns 120 arranged in the X-direction. Those semiconductor column rows SC provided at 5n+1^{th} through 5n+4^{th} positions (where n is an integer from 0 to 4) counting from one side in the Y-direction, of these 24 semiconductor column rows SC are included in the string units SU. Moreover, those semiconductor column rows SC provided at 5^{th}, 10^{th}, 15^{th}, and 20^{th} positions counting from the one side in the Y-direction, of these 24 semiconductor column rows SC are provided at positions overlapping the inter-string unit insulating members SHE, viewed in the Z-direction, and do not function as a device.

The semiconductor column 120 includes the likes of polycrystalline silicon (Si), for example. As shown in FIG. 4, for example, the semiconductor column 120 has a substantially cylindrical shape, and, an insulating column 127 of the likes of silicon oxide (SiO₂) is provided in a central portion of the semiconductor column 120.

The semiconductor column 120 comprises: a region 121 provided in a lower end portion of the semiconductor column 120; a region 122 provided above the region 121, but provided below an upper surface of the uppermost conductive layer 110; and a region 123 provided above the region 122.

The region 121 includes an N-type impurity such as phosphorus (P). The region 121 comprises a substantially cylindrical shape. The region 121 is connected to the conductive layer 113.

The region 122 faces the plurality of conductive layers 110. The region 122 functions as channel regions of the memory cells MC (FIG. 1), the dummy memory cells DMD, DMS (FIG. 1), and the select transistors STDT, STD, STS, STSB (FIG. 1). The region 122 need not include an N-type impurity such as phosphorus (P).

The region 123 includes an N-type impurity such as phosphorus (P). The region 123 is electrically connected to the bit line BL extending in the Y-direction (FIG. 3), via a contact electrode Ch and contact electrode Vy extending in the Z-direction (FIG. 3). The contact electrode Ch and contact electrode Vy may include the likes of a stacked film having stacked therein a barrier conductive film of the likes of titanium nitride (TiN) and a metal film of the likes of tungsten (W), for example.

The bit line BL may include the likes of a stacked film having stacked therein a barrier conductive film of the likes of titanium nitride (TiN) and a metal film of the likes of copper (Cu), for example.

As shown in FIG. 5, for example, the gate insulating film 130 comprises a tunnel insulating film 131, an electric charge accumulating film 132, and a block insulating film 133 that are stacked between the semiconductor column 120 and the conductive layer 110. The tunnel insulating film 131 and the block insulating film 133 include the likes of silicon oxide (SiO₂), for example. The electric charge accumulating film 132 is a film capable of accumulating a charge, of the likes of silicon nitride (SiN), for example. The gate insulating film 130 has a substantially cylindrical shape, and extends in the Z-direction along an outer peripheral surface of the semiconductor column 120 excluding a contact portion of the semiconductor column 120 and the conductive layer 113.

As shown in FIGS. 3 and 4, for example, the inter-finger structure ST comprises: an inter-finger electrode 141 extending in the X-direction and the Z-direction; and an inter-finger insulating member 142 of the likes of silicon oxide (SiO₂), provided on a side surface in the Y-direction of the inter-finger electrode 141. A lower end of the inter-finger electrode 141 is connected to the conductive layer 113. Moreover, an upper end of the inter-finger electrode 141 is located above the upper surface of the uppermost conductive layer 110. The inter-finger electrode 141 may include the likes of a stacked film having stacked therein a barrier conductive film of the likes of titanium nitride (TiN) and a metal film of the likes of tungsten (W), for example. Moreover, the inter-finger electrode 141 may include the likes of polycrystalline silicon including an impurity such as phosphorus (P) or boron (B), for example. The inter-finger electrode 141 functions as a part of the source line SL (FIG. 1), for example. In addition, the inter-finger structure ST does not need to have the inter-finger electrode 141.

The inter-string unit insulating member SHE includes the likes of silicon oxide (SiO₂), for example. As shown in FIG. 3, for example, the inter-string unit insulating member SHE is provided between two string units SU arranged in the Y-direction in the finger structure FS, and extends in the X-direction. As shown in FIG. 4, the inter-string unit insulating member SHE extends in the Z-direction within a height range corresponding to the insulating layer 102, the conductive layers 110(SGDT), 110(SGD), and the part of the conductive layers 110(DWD), and to the insulating layers 101 provided on upper and lower surfaces of these conductive layers 110, and divides these configurations in the Y-direction.

### [Structure in Hookup Region R_{HU}]

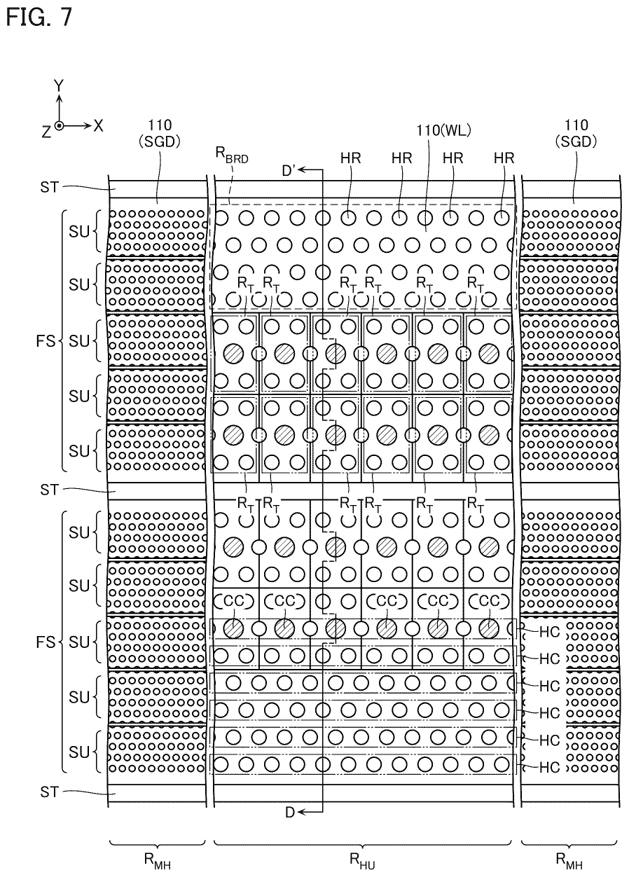

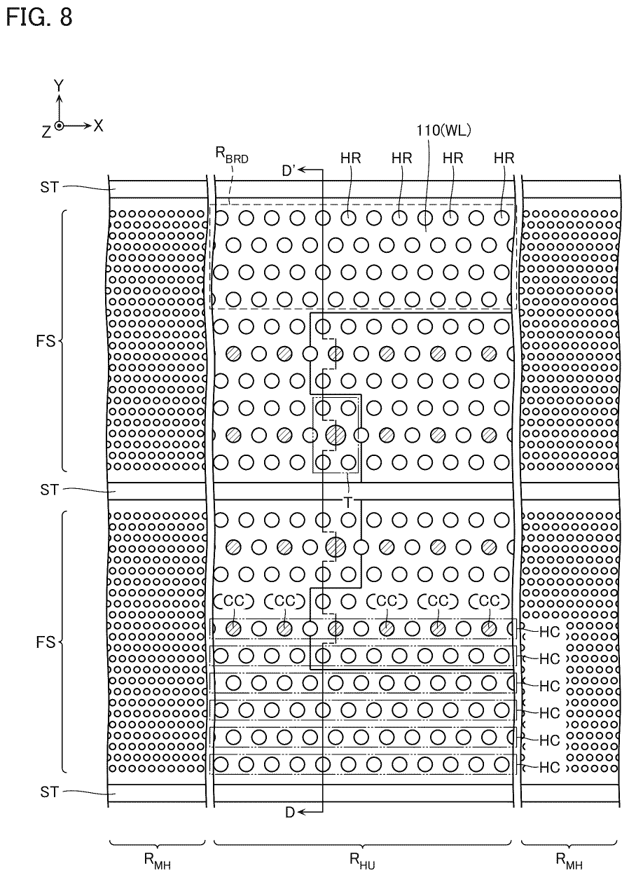

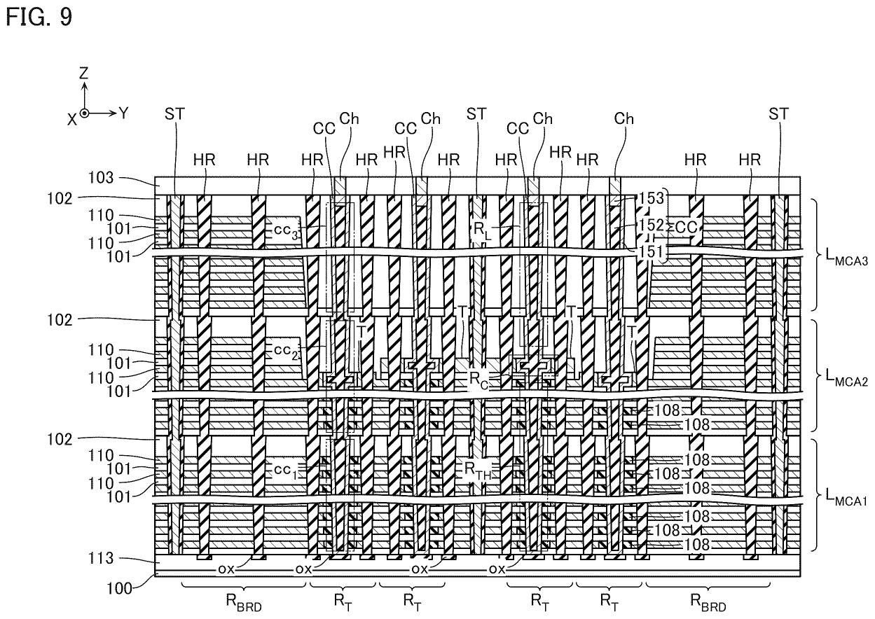

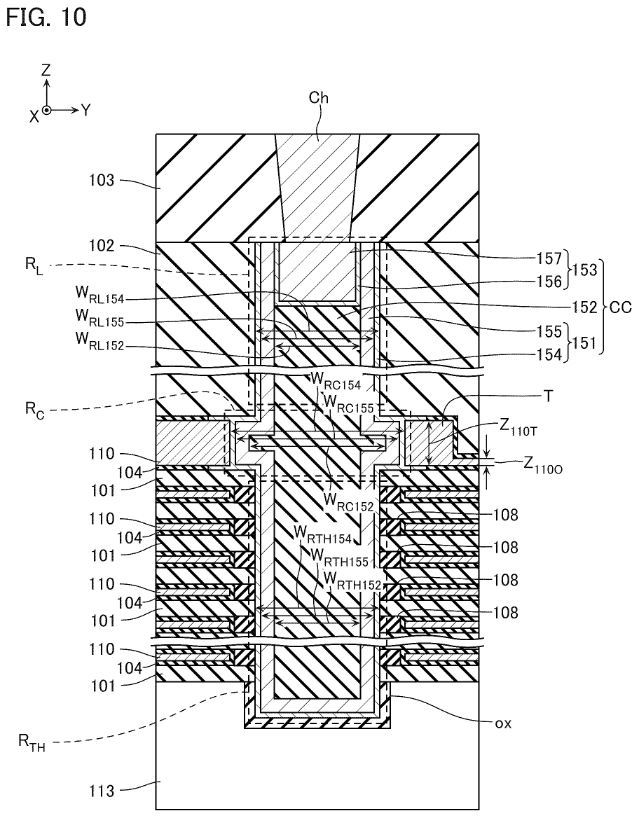

Next, structure in the hook-up region R_{HU} will be described with reference to FIGS. 7 to 10. FIGS. 7 and 8 are schematic plan views for explaining the hook-up region R_{HU}. In FIG. 7, the insulating layers 102, 103, the conductive layer 110(SGDT), and so on, are omitted. FIG. 8 shows an XY cross section at a height position corresponding to one of the conductive layers 110(WL). FIG. 9, which is a schematic cross-sectional view of the hook-up region R_{HU}, shows a cross section of the structure shown in FIGS. 7 and 8 taken along the line D-D′ and viewed along a direction of the arrows. FIG. 10, which is a schematic cross-sectional view of the hook-up region R_{HU}, shows a part of FIG. 9 enlarged.

The hook-up region R_{HU} exemplified in FIG. 7 comprises a bridge region R_{BRD} and a plurality of terrace regions R_{T}.

The bridge region R_{BRD} comprises the conductive layers 110(WL), 110(DWD), 110(DWS), 110(SGS), 110(SGSB).

As exemplified in FIGS. 8 and 9, the conductive layers 110(WL), 110(DWD), 110(DWS), 110(SGS), 110(SGSB) extend in the X-direction from an end portion on one side in the X-direction of the hook-up region R_{HU} to an end portion on the other side in the X-direction of the hook-up region R_{HU}, in the bridge region R_{BRD}.

The terrace regions R_{T}, a plurality of which are provided corresponding to the plurality of conductive layers 110 arranged in the Z-direction, are provided on one side in the Y-direction with respect to the bridge region R_{BRD}. These plurality of terrace regions R_{T} each comprise a terrace portion T of a corresponding conductive layer 110. The terrace portion T is a portion that, viewed from above, does not overlap another conductive layer 110, for example. As shown in FIG. 9, the terrace portion T is covered by the insulating layer 102. Note that in the present embodiment, as shown in FIG. 10, for example, thickness Z_{110T} in the Z-direction of the terrace portion T of the conductive layer 110 is greater than thickness Z_{110O} in the Z-direction of a portion different from the terrace portion T of the conductive layer 110.

Moreover, the hook-up region R_{HU} is provided with a plurality of support insulating columns HR. The support insulating column HR may include silicon oxide (SiO₂), or may comprise a configuration corresponding to the semiconductor column 120, the insulating column 127, and the gate insulating film 130, for example. As shown in FIG. 9, the support insulating column HR extends in the Z-direction over the three memory cell array layers L_{MCA1}, L_{MCA2}, L_{MCA3}. Each of outer peripheral surfaces of the support insulating columns HR is surrounded by through-holes provided in the insulating layer 102 and in the plurality of conductive layers 110 and the plurality of insulating layers 101. Moreover, in the example illustrated, a lower end portion of the support insulating column HR is covered by an oxide layer ox provided between the conductive layer 113 and the lower end portion of the support insulating column HR.

As shown in FIG. 7, for example, the support insulating columns HR are arranged in a certain pattern in the X-direction and the Y-direction. For example, the finger structure FS comprises 10 support insulating column rows HC provided from one side in the Y-direction to the other side in the Y-direction. These 10 support insulating column rows HC each comprise a plurality of the support insulating columns HR arranged in the X-direction. Note that in the example illustrated, in a part of the support insulating column rows HC provided at positions corresponding to the terrace regions R_{T}, a part of the support insulating columns HR are omitted, and contact electrodes CC provided instead.

The respective contact electrodes CC are provided corresponding to the plurality of terrace portions T. As shown in FIG. 9, the contact electrode CC extends in the Z-direction over the three memory cell array layers L_{MCA1}, L_{MCA2}, L_{MCA3}. An upper end portion of the contact electrode CC is connected to the contact electrode Ch.

The contact electrode CC comprises three tiered portions cc₁, cc₂, cc₃ arranged in the Z-direction corresponding to the three memory cell array layers L_{MCA1}, L_{MCA2}, L_{MCA3}. For example, diameters of each of the tiered portions cc₁, cc₂, cc₃ increase from their lower ends upwards. That is, widths in the X-direction and the Y-direction (diameters and cross-sectional areas in an XY cross section) at upper ends of the tiered portions cc₁, cc₂, cc₃ are greater than widths in the X-direction and the Y-direction (diameters and cross-sectional areas in an XY cross section) at lower ends of the tiered portions cc₁, cc₂, cc₃. Moreover, at boundaries of the memory cell array layers L_{MCA1}, L_{MCA2}, L_{MCA3}, a diameter (and a cross-sectional area) of a lower side portion of the contact electrode CC is greater than a diameter (and a cross-sectional area) of an upper side portion of the contact electrode CC, so that shapes of respective side surfaces at tier boundaries of the three tiered portions cc₁, cc₂, cc₃ in the contact electrode CC, are discontinuously formed.

Note that the tiered portions cc₁, cc₂, cc₃ may have a bowing shape where their widths in the X-direction and the Y-direction (diameters and cross-sectional areas in an XY cross section) will be maximum at a height position between their upper end and lower end. Now, at boundaries of the memory cell array layers L_{MCA1}, L_{MCA2}, L_{MCA3}, the diameter (and the cross-sectional area) of the lower side portion of the contact electrode CC and the diameter (and the cross-sectional area) of the upper side portion of the contact electrode CC may be substantially equal. With such a configuration, too, shapes of respective side surfaces at tier boundaries of the three tiered portions cc₁, cc₂, cc₃ in the contact electrode CC, will be formed discontinuously.

Moreover, the contact electrode CC comprises: a connecting region R_{C} which is provided at a height position corresponding to the terrace portion T of a corresponding conductive layer 110, and contacts the terrace portion T of this conductive layer 110; a lead-out region R_{L} which is provided above the connecting region R_{C} and extends in the Z-direction; and a through region R_{TH} which is provided below the connecting region R_{C} and extends in the Z-direction. For example, FIG. 9 shows a contact electrode CC corresponding to a conductive layer 110 in the memory cell array layer L_{MCA2}. The connecting region R_{C} of this contact electrode CC is provided in the memory cell array layer L_{MCA2}. An outer peripheral surface of the connecting region R_{C} contacts the conductive layer 110. An outer peripheral surface of the lead-out region R_{L} is surrounded by a through-hole provided in the insulating layer 102. An outer peripheral surface of the through region R_{TH} is surrounded by a through-hole provided in the plurality of conductive layers 110 and the plurality of insulating layers 101.

Moreover, the contact electrode CC comprises: a conductive member 151 which extends in the Z-direction over the three memory cell array layers L_{MCA1}, L_{MCA2}, L_{MCA3}; an insulating column 152 which extends in the Z-direction over the three memory cell array layers L_{MCA1}, L_{MCA2}, L_{MCA3}, and has an outer peripheral surface covered by the conductive member 151; and a conductive member 153 which is provided in an upper end portion of the contact electrode CC, has an outer peripheral surface contacting the conductive member 151, and has an upper surface contacting the contact electrode Ch.

An outer peripheral surface of a portion provided in the connecting region R_{C}, of the conductive member 151 contacts the conductive layer 110. A portion provided in the lead-out region R_{L}, of the conductive member 151 extends in the Z-direction penetrating the insulating layer 102. A portion provided in the through region R_{TH}, of the conductive member 151 extends in the Z-direction penetrating the plurality of conductive layers 110 arranged in the Z-direction. Moreover, an outer peripheral surface of the portion provided in the through region R_{TH}, of the conductive member 151 is provided with a plurality of insulating layers 108 arranged in the Z-direction corresponding to the plurality of conductive layers 110. The conductive member 151 is insulated from the plurality of conductive layers 110 via these plurality of insulating layers 108. The insulating layer 108 may include the likes of silicon oxide (SiO₂). Moreover, in the example illustrated, a lower end portion of the conductive member 151 is provided below the upper surface of the conductive layer 113, and the lower end portion of the conductive member 151 is covered by the oxide layer ox provided between the conductive layer 113 and the lower end portion of the conductive member 151. The conductive member 151 is insulated from the conductive layer 113 via this oxide layer ox. The oxide layer ox may include the likes of silicon oxide (SiO₂).

As shown in FIG. 10, for example, the conductive member 151 comprises: a barrier conductive film 154 extending in the Z-direction; and a metal film 155 which extends in the Z-direction, has an outer peripheral surface and lower end portion covered by the barrier conductive film 154, and contacts the barrier conductive film 154. The barrier conductive film 154 may include the likes of titanium nitride (TiN) or tantalum nitride (TaN), for example. The metal film 155 may include the likes of tungsten (W), molybdenum (Mo), or ruthenium (Ru), for example. The barrier conductive film 154 and the metal film 155 extend in the Z-direction over the lead-out region R_{L}, the connecting region R_{C}, and the through region R_{TH}.

Portions provided in the lead-out region R_{L}, connecting region R_{C}, and through region R_{TH}, of the barrier conductive film 154 and metal film 155 are each formed in a substantially cylindrical shape. In FIG. 10, widths in the X-direction and the Y-direction (diameters in an XY cross section) of the portions provided in the connecting region R_{C}, of the barrier conductive film 154 and the metal film 155 are respectively indicated as widths W_{RC154}, W_{RC155}. Similarly, widths in the X-direction and the Y-direction (diameters in an XY cross section) of the portions provided in the lead-out region R_{L}, of the barrier conductive film 154 and the metal film 155 are respectively indicated as widths W_{RL154}, W_{RL155}. Similarly, widths in the X-direction and the Y-direction (diameters in an XY cross section) of the portions provided in the through region R_{TH}, of the barrier conductive film 154 and the metal film 155 are respectively indicated as widths W_{RTH154}, W_{RTH155}. The width W_{RC154} is greater than the widths W_{RL154}, W_{RTH154}. The width W_{RC155} is greater than the widths W_{RL155}, W_{RTH155}.

The insulating column 152 may include the likes of silicon oxide (SiO₂), for example. The insulating column 152 extends in the Z-direction over the lead-out region R_{L}, the connecting region R_{C}, and the through region R_{TH}. An upper end portion of the insulating column 152 is covered by the conductive member 153, and contacts the conductive member 153 (more specifically, a later-mentioned barrier conductive film 156). A lower end portion and outer peripheral surface of the insulating column 152 are covered by the conductive member 151, and contact the conductive member 151 (more specifically, the metal film 155).

Portions provided in the lead-out region R_{L}, connecting region R_{C}, and through region R_{TH}, of the insulating column 152 are each formed in a substantially circular column-like shape. In FIG. 10, a width in the X-direction and the Y-direction (a diameter in an XY cross section) of the portion provided in the connecting region R_{C}, of the insulating column 152 is indicated as a width W_{RC152}. Similarly, a width in the X-direction and the Y-direction (a diameter in an XY cross section) of the portion provided in the lead-out region R_{L}, of the insulating column 152 is indicated as a width W_{RL152}. Similarly, a width in the X-direction and the Y-direction (a diameter in an XY cross section) of the portion provided in the through region R_{TH}, of the insulating column 152 is indicated as width W_{RTH152}. The width W_{RC152} is greater than the widths W_{RL152}, W_{RTH152}.

The conductive member 153 comprises: a barrier conductive film 156 extending in the Z-direction; and a metal film 157 which extends in the Z-direction, has an outer peripheral surface and lower end portion covered by the barrier conductive film 156, and contacts the barrier conductive film 156. The barrier conductive film 156 may include the likes of titanium nitride (TiN) or tantalum nitride (TaN), for example. The metal film 157 may include the likes of tungsten (W), molybdenum (Mo), or ruthenium (Ru), for example.

### [Method of Manufacturing]

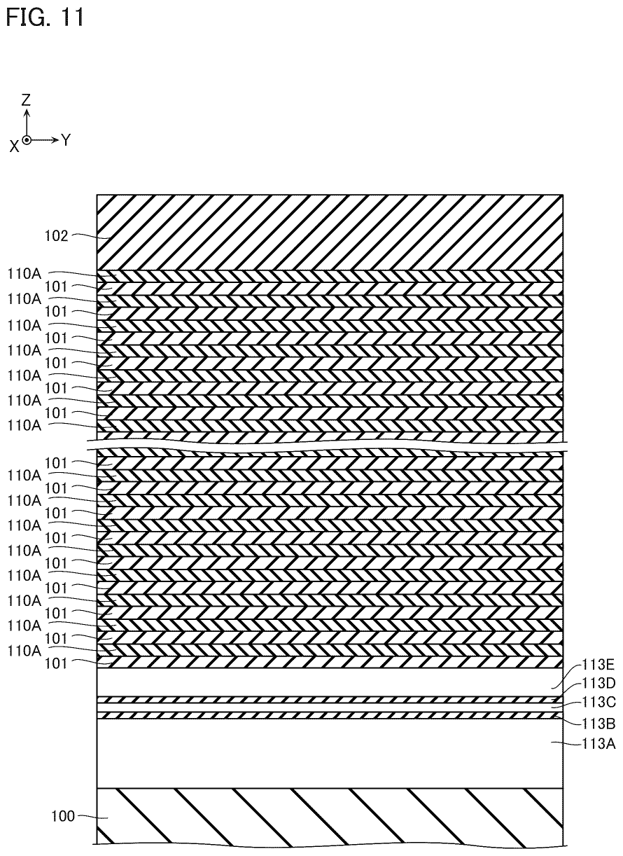

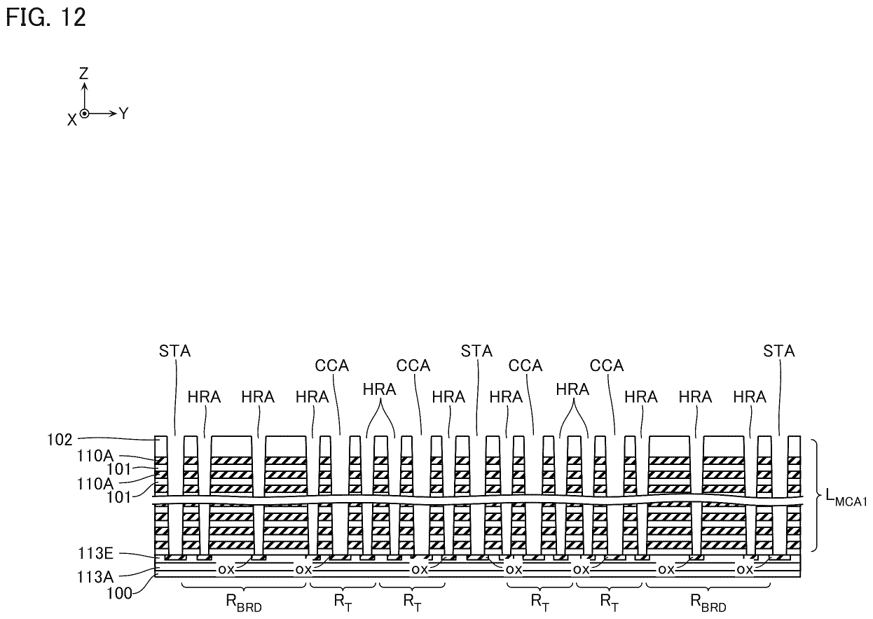

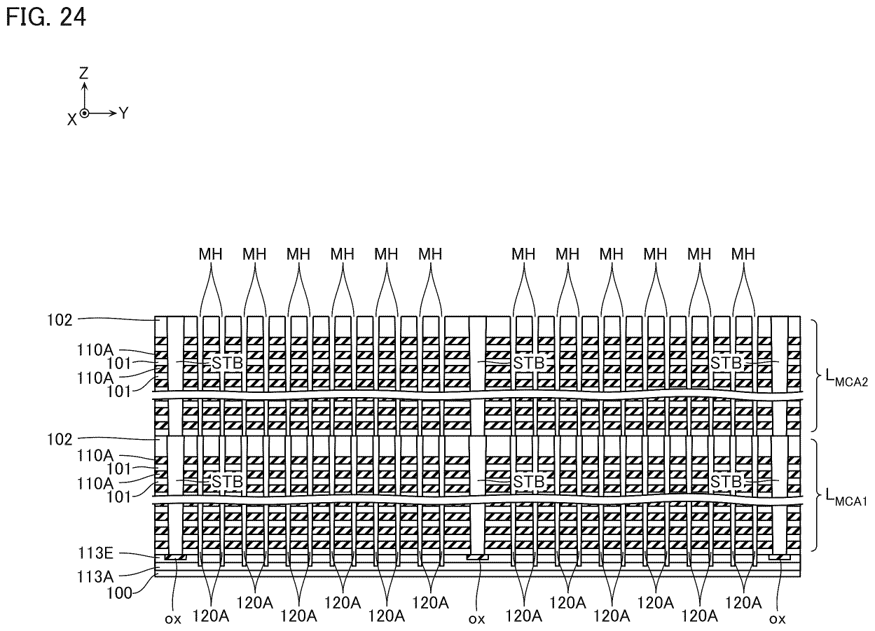

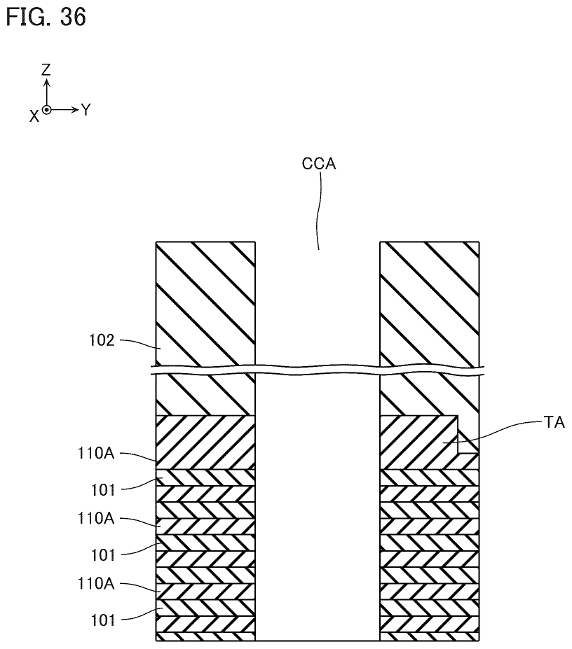

Next, a method of manufacturing the semiconductor memory device according to the first embodiment will be described with reference to FIGS. 11 to 59. FIGS. 11 to 59 are schematic cross-sectional views for explaining same method of manufacturing. FIGS. 11, 14, 15, 30, and 42 to 50 show cross sections corresponding to FIG. 4. FIGS. 12, 13, 16 to 23, 26, 27, 31 to 35, 40, 41, and 51 show cross sections corresponding to FIG. 9. FIGS. 24, 25, 28, and 29 show cross sections corresponding to FIG. 6. FIGS. 36 to 39, and 52 to 59 show cross sections corresponding to FIG. 10.

When manufacturing the semiconductor memory device according to the present embodiment, as shown in FIG. 11, for example, the insulating layer 100 is formed above an unillustrated semiconductor substrate. Next, a semiconductor layer 113A of the likes of silicon, a sacrifice layer 113B of the likes of silicon oxide, a sacrifice layer 113C of the likes of silicon, a sacrifice layer 113D of the likes of silicon oxide, and a semiconductor layer 113E of the likes of silicon, are formed on the insulating layer 100. In addition, the plurality of insulating layers 101 and a plurality of sacrifice layers 110A corresponding to the memory cell array layer L_{MCA1}, are alternately formed. The sacrifice layer 110A includes the likes of silicon nitride (SiN), for example. In addition, a part of the insulating layer 102 corresponding to the memory cell array layer L_{MCA1} is formed. This step is performed by a method such as CVD (Chemical Vapor Deposition), for example.

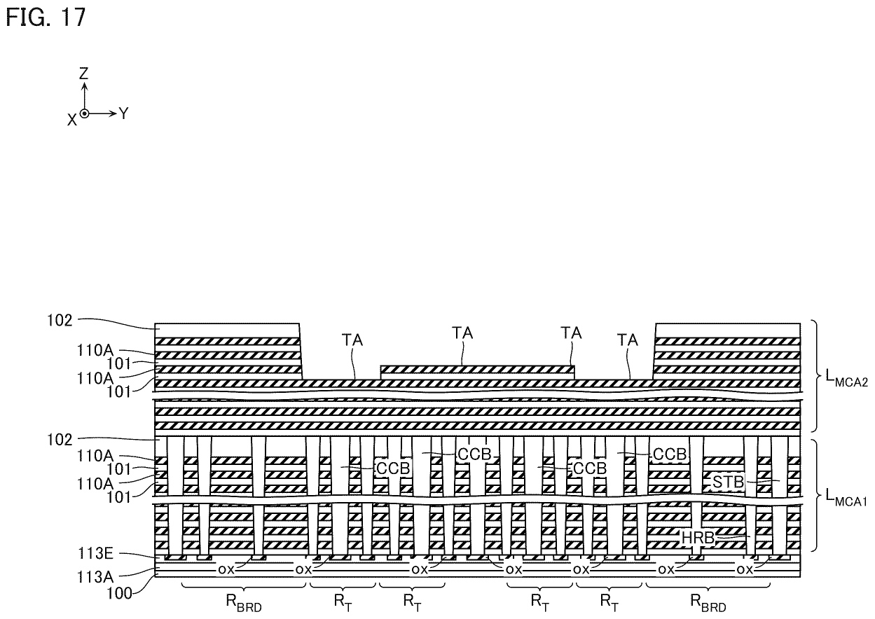

Next, though illustration of the following is omitted, the insulating layer 102, the plurality of insulating layers 101, and the plurality of sacrifice layers 110A are partially removed in the plurality of terrace regions R_{T} in the hook-up region R_{HU}, and a plurality of terrace portions TA (refer to FIG. 17) are formed. The terrace portion TA is a portion of the sacrifice layer 110A that, viewed from above, does not overlap another sacrifice layer 110A, for example. In this step, for example, a resist is formed on an upper surface of the insulating layer 102 corresponding to the memory cell array layer L_{MCA1}. Moreover, removal of the sacrifice layer 110A, removal of the insulating layer 101, and removal of a part of the resist are repeatedly performed. Removal of the resist is performed by isotropic etching, such as wet etching.

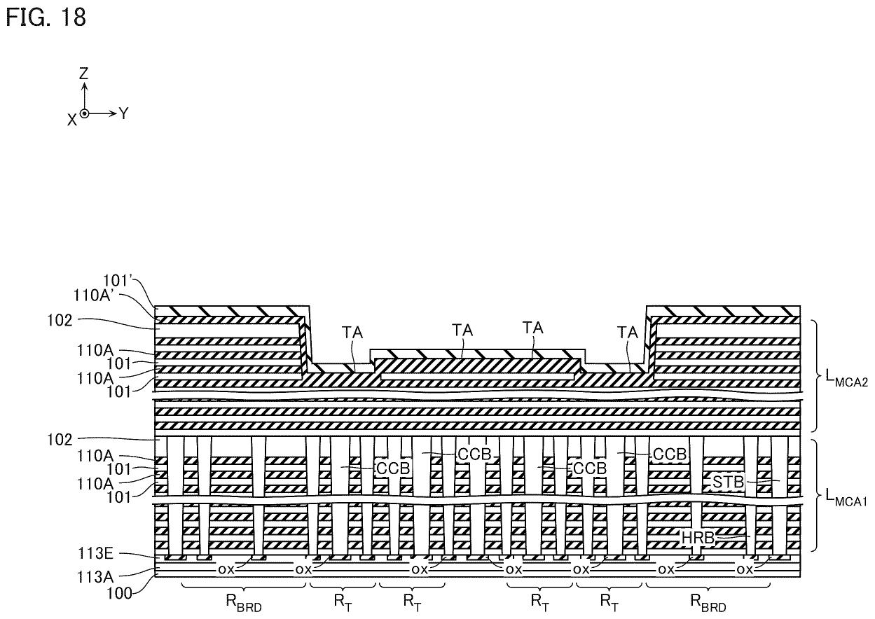

Next, though illustration of the following is omitted, the terrace portion TA undergoes film thickening by a method of the kind mentioned later with reference to FIGS. 18 to 20, for example.

Next, though illustration of the following is omitted, a part of the insulating layer 102 corresponding to the memory cell array layer L_{MCA1} is formed. This step is performed by a method such as CVD, for example.

Next, as shown in FIG. 12, for example, via holes HRA are formed at positions corresponding to the support insulating columns HR. Moreover, contact holes CCA are formed at positions corresponding to the contact electrodes CC. Moreover, trenches STA are formed at positions corresponding to the inter-finger structures ST. These via holes HRA, contact holes CCA, and trenches STA extend in the Z-direction, penetrate the insulating layer 102 and the insulating layers 101 and sacrifice layers 110A corresponding to the memory cell array layer L_{MCA1}, and expose an upper surface of the semiconductor layer 113E. This step is performed by a method such as RIE (Reactive Ion Etching), for example.

Next, the semiconductor layer 113E is oxidized at bottom surfaces of the via holes HRA, the contact holes CCA, and the trenches STA, whereby the oxide layers ox are formed. In this step, polycrystalline silicon is selectively oxidized, without silicon nitride being oxidized, by a method such as thermal oxidation process, for example.

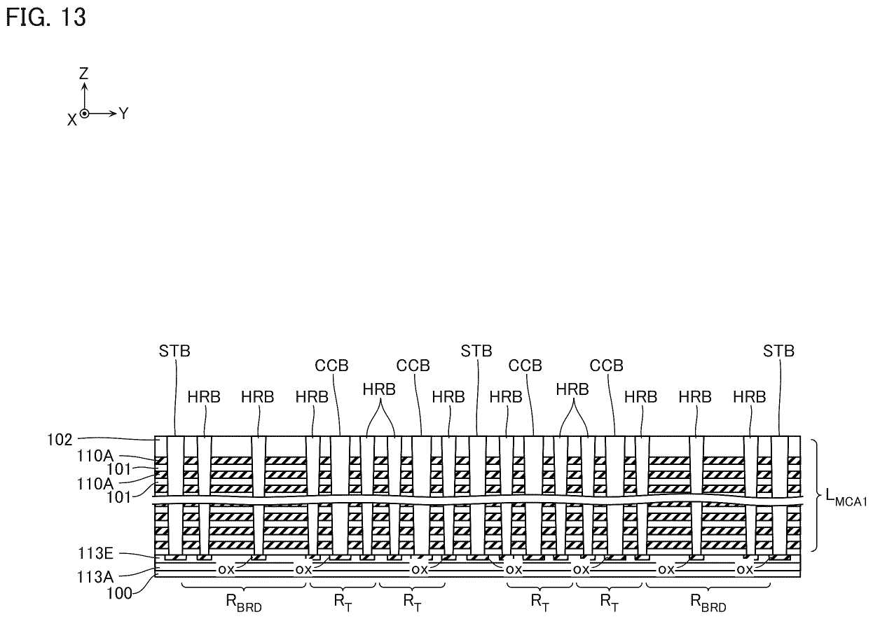

Next, as shown in FIG. 13, for example, sacrifice films HRB, CCB, STB of the likes of polycrystalline silicon are formed in the via holes HRA, the contact holes CCA, and the trenches STA, at a height position corresponding to the memory cell array layer L_{MCA1}. This step is performed by a method such as CVD, for example.

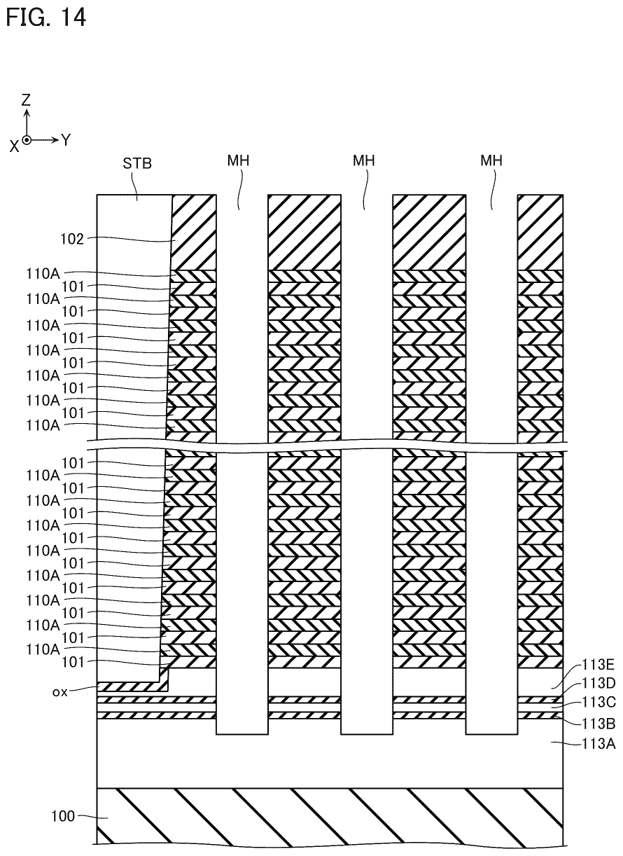

Next, as shown in FIG. 14, for example, memory holes MH are formed at positions corresponding to the semiconductor columns 120. These memory holes MH extend in the Z-direction, penetrate the insulating layer 102, the insulating layers 101 and sacrifice layers 110A corresponding to the memory cell array layer L_{MCA1}, and the semiconductor layer 113E, sacrifice layer 113D, sacrifice layer 113C, and sacrifice layer 113B, and expose an upper surface of the semiconductor layer 113A. This step is performed by a method such as RIE, for example.

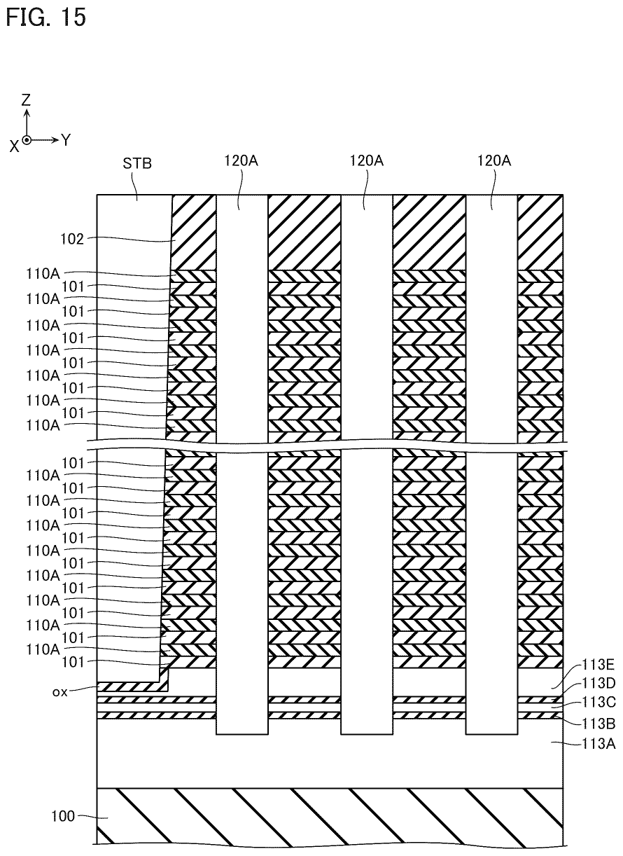

Next, as shown in FIG. 15, for example, sacrifice films 120A are formed inside the memory holes MH at the height position corresponding to the memory cell array layer L_{MCA1}. This step is performed by a method such as CVD, for example.

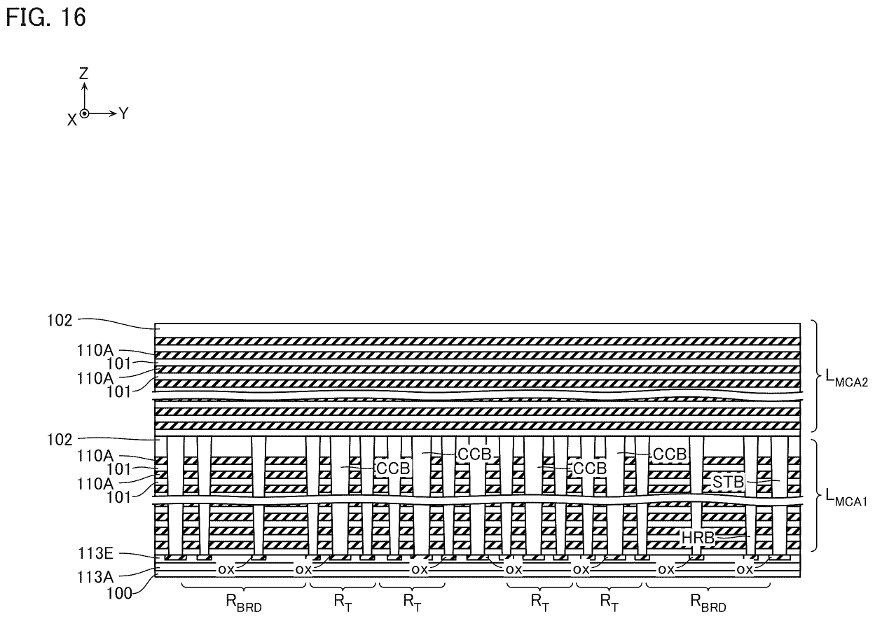

Next, as shown in FIG. 16, for example, the plurality of insulating layers 101 and a plurality of sacrifice layers 110A corresponding to the memory cell array layer L_{MCA2}, are alternately formed. Moreover, a part of the insulating layer 102 corresponding to the memory cell array layer L_{MCA2} is formed. This step is performed by a method such as CVD, for example.

Next, as shown in FIG. 17, for example, the insulating layer 102, the plurality of insulating layers 101, and the plurality of sacrifice layers 110A are partially removed in the plurality of terrace regions R_{T} in the hook-up region R_{HU}, and a plurality of the terrace portions TA are formed. In this step, for example, a resist is formed on an upper surface of the insulating layer 102 corresponding to the memory cell array layer L_{MCA2}. Moreover, removal of the sacrifice layer 110A, removal of the insulating layer 101, and removal of a part of the resist are repeatedly performed. Note that removal of the resist is performed by isotropic etching, such as wet etching.

Next, as shown in FIG. 18, for example, a sacrifice layer 110A′ and an insulating layer 101′ are formed on an upper surface of the insulating layer 102, upper surfaces of the terrace portions TA, and side surfaces formed along with the terrace portions TA, of the plurality of sacrifice layers 110A and insulating layers 101, corresponding to the memory cell array layer L_{MCA2}. The sacrifice layer 110A′ includes the likes of silicon nitride (SiN), for example. Portions formed on the upper surfaces of the terrace portions TA, of the sacrifice layer 110A′ becomes parts of the terrace portions TA, whereby the terrace portions TA of the sacrifice layer 110A undergoes film thickening. The insulating layer 101′ includes the likes of silicon oxide (SiO₂), for example.

Film thickness of portions formed above the upper surface of the insulating layer 102 and upper surfaces of the terrace portions TA corresponding to the memory cell array layer L_{MCA2}, of the insulating layer 101′ is greater than film thickness of portions formed along the above-described side surfaces of the plurality of sacrifice layers 110A and insulating layers 101 corresponding to the memory cell array layer L_{MCA2}, of the insulating layer 101'. This step is performed by a method such as CVD, for example.

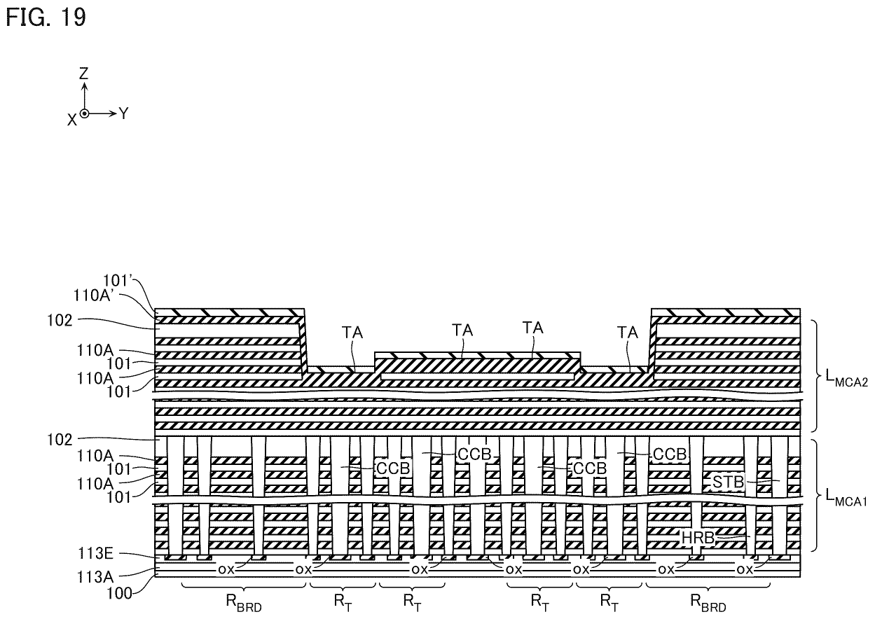

Next, as shown in FIG. 19, for example, parts of the insulating layer 101′ are removed to expose the portion formed on the above-described side surfaces of the plurality of sacrifice layers 110A and insulating layers 101, of the sacrifice layer 110A'. In this step, the portions formed above the upper surface of the insulating layer 102 and the upper surfaces of the terrace portions TA corresponding to the memory cell array layer L_{MCA2}, of the insulating layer 101′ are left. This step is performed by a method such as wet etching, for example.

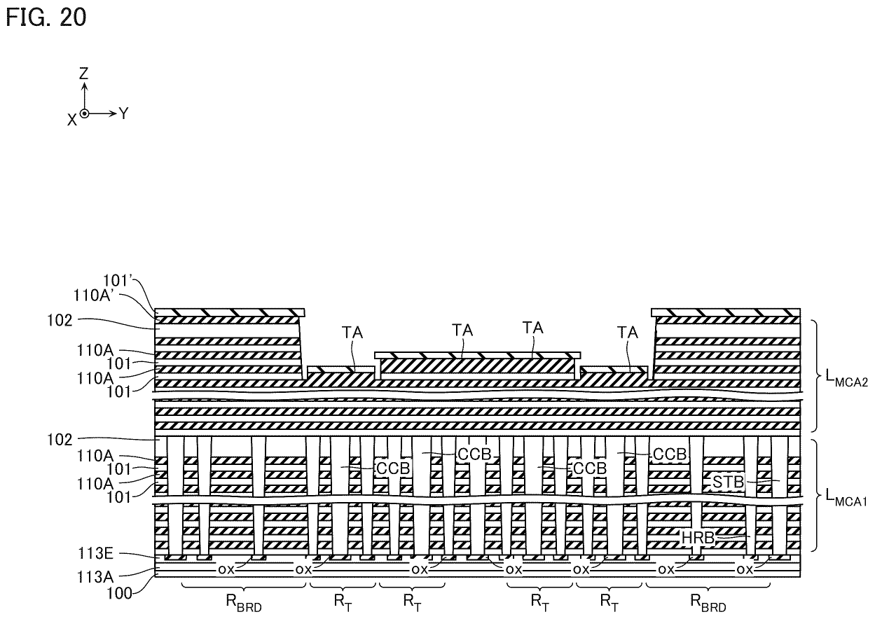

Next, as shown in FIG. 20, for example, the exposed parts of the sacrifice layer 110A′ are removed to expose the above-described side surfaces of the plurality of sacrifice layers 110A and insulating layers 101. In this step, the film-thickened terrace portions TA are each divided from other terrace portions TA (from the sacrifice layers 110A formed in the other terrace portions TA). This step is performed by a method such as wet etching, for example.

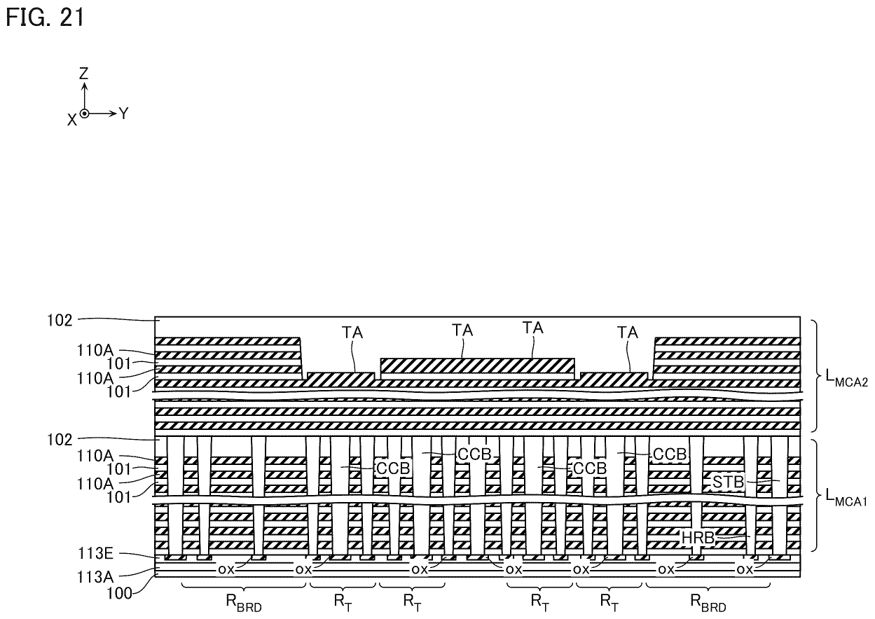

Next, as shown in FIG. 21, for example, a part of the insulating layer 102 corresponding to the memory cell array layer L_{MCA2} is formed by a method such as CVD. Moreover, planarization of the insulating layer 102 is performed by a method such as CMP (Chemical Mechanical Polishing), and the portions formed on the upper surface of the insulating layer 102 in the step described with reference to FIG. 18, of the insulating layer 101′ and sacrifice layer 110A′ are removed.

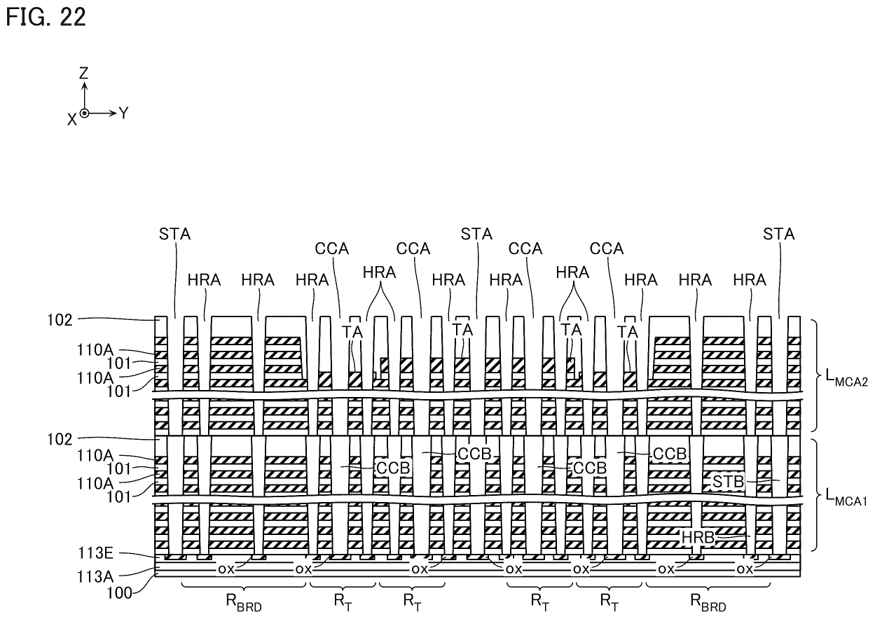

Next, as shown in FIG. 22, for example, via holes HRA are formed at positions corresponding to the support insulating columns HR. Moreover, contact holes CCA are formed at positions corresponding to the contact electrodes CC. Moreover, trenches STA are formed at positions corresponding to the inter-finger structures ST. These via holes HRA, contact holes CCA, and trenches STA extend in the Z-direction, penetrate the insulating layer 102 and the insulating layers 101 and sacrifice layers 110A corresponding to the memory cell array layer L_{MCA2}, and expose upper ends of the sacrifice films HRB, CCB, STB provided at the height position corresponding to the memory cell array layer L_{MCA1}. This step is performed by a method such as RIE, for example.

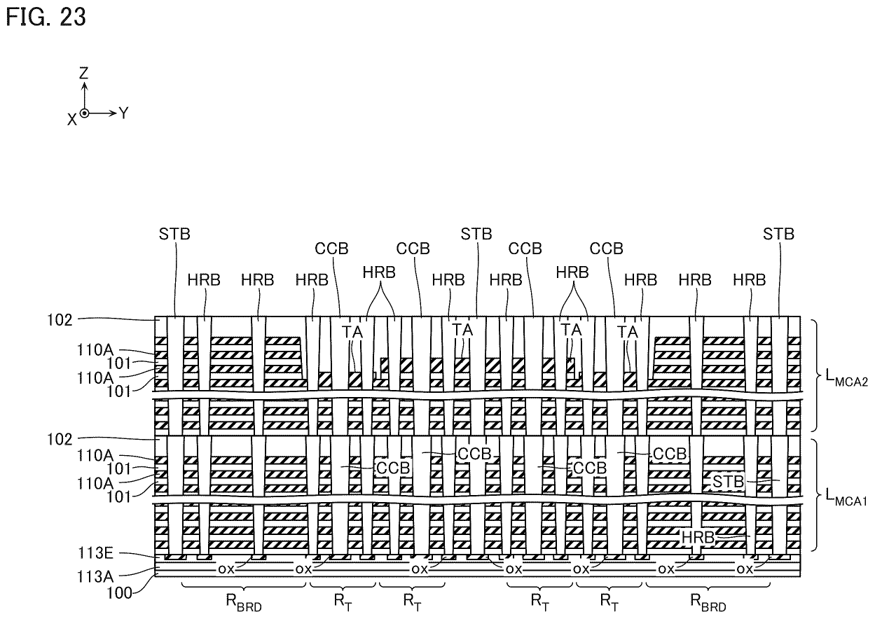

Next, as shown in FIG. 23, for example, sacrifice films HRB, CCB, STB of the likes of polycrystalline silicon are formed in the via holes HRA, the contact holes CCA, and the trenches STA, at a height position corresponding to the memory cell array layer L_{MCA2}. This step is performed by a method such as CVD, for example.

Next, as shown in FIG. 24, for example, memory holes MH are formed at positions corresponding to the semiconductor columns 120. These memory holes MH extend in the Z-direction, penetrate the insulating layer 102 and the insulating layers 101 and sacrifice layers 110A corresponding to the memory cell array layer L_{MCA2}, and expose upper surfaces of the sacrifice films 120A provided at the height position corresponding to the memory cell array layer L_{MCA1}. This step is performed by a method such as RIE, for example.

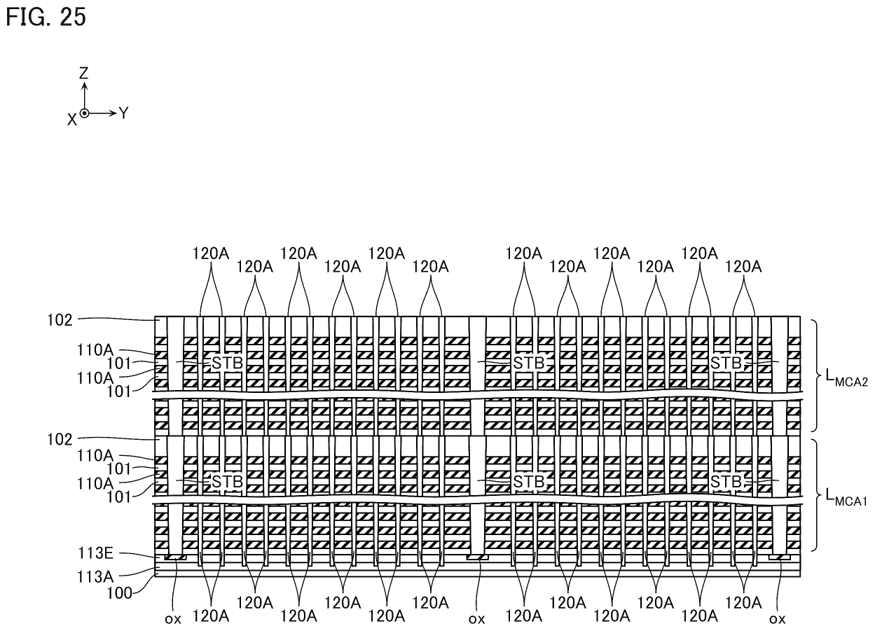

Next, as shown in FIG. 25, for example, sacrifice films 120A are formed inside the memory holes MH at the height position corresponding to the memory cell array layer L_{MCA2}. This step is performed by a method such as CVD, for example.

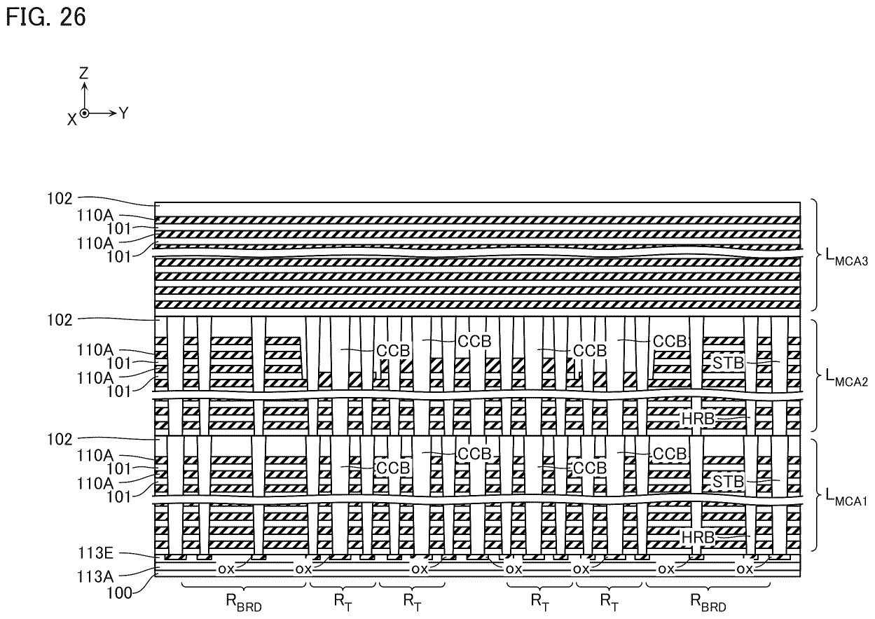

Next, as shown in FIG. 26, for example, the plurality of insulating layers 101 and a plurality of sacrifice layers 110A corresponding to the memory cell array layer L_{MCA3}, are alternately formed. Moreover, a part of the insulating layer 102 corresponding to the memory cell array layer L_{MCA3} is formed. This step is performed by a method such as CVD, for example.

Next, though illustration of the following is omitted, the insulating layer 102, the plurality of insulating layers 101, and the plurality of sacrifice layers 110A are partially removed in the plurality of terrace regions R_{T} in the hook-up region R_{HU}, and a plurality of terrace portions TA (refer to FIG. 17) are formed. This step is executed similarly to the step described with reference to FIG. 17, for example.

Next, though illustration of the following is omitted, the terrace portion TA undergoes film thickening by a method of the kind described with reference to FIGS. 18 to 20, for example.

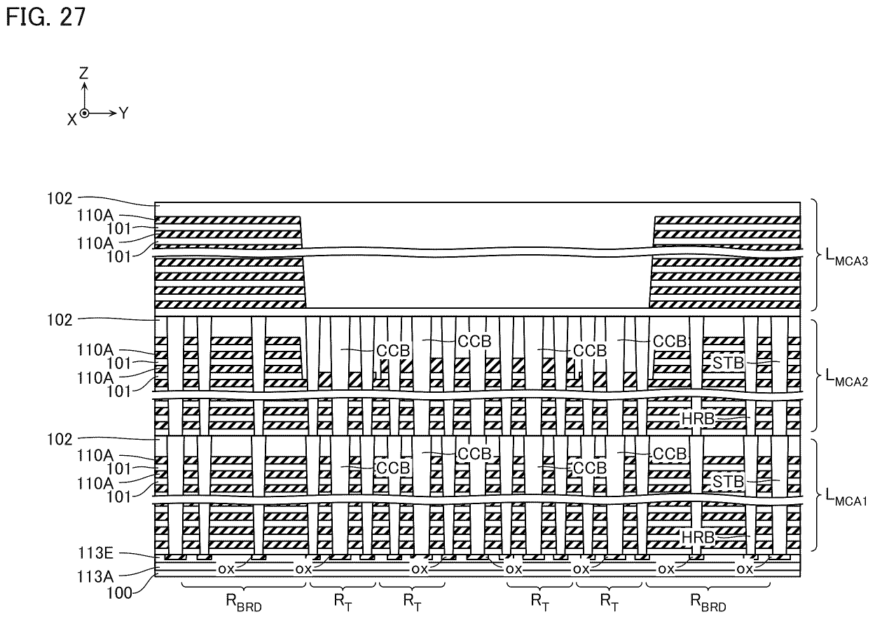

Next, as shown in FIG. 27, for example, a part of the insulating layer 102 corresponding to the memory cell array layer L_{MCA3} is formed. This step is performed by a method such as CVD, for example.

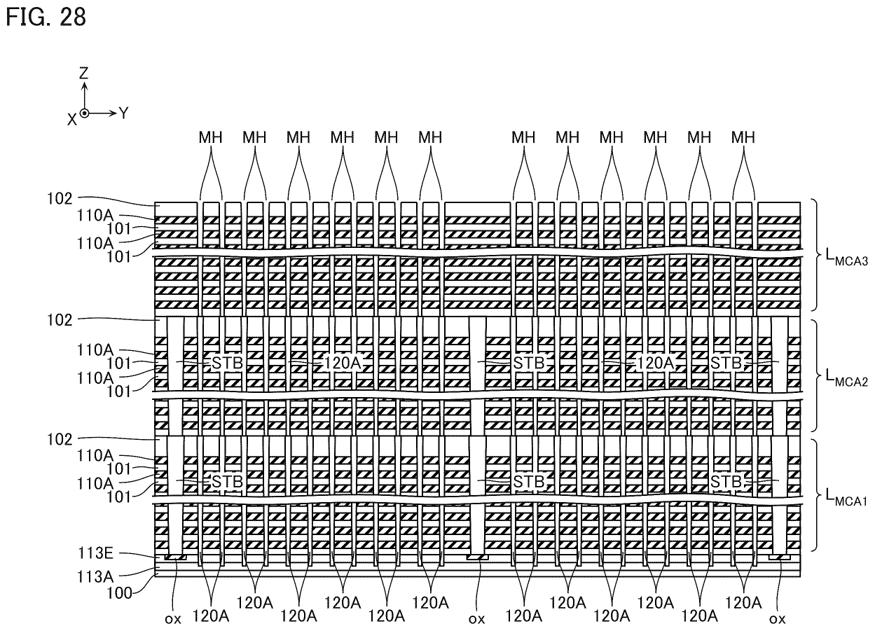

Next, as shown in FIG. 28, for example, memory holes MH are formed at positions corresponding to the semiconductor columns 120. These memory holes MH extend in the Z-direction, penetrate the insulating layer 102 and the insulating layers 101 and sacrifice layers 110A corresponding to the memory cell array layer L_{MCA3}, and expose upper surfaces of the sacrifice films 120A provided at the height position corresponding to the memory cell array layer L_{MCA2}. This step is performed by a method such as RIE, for example.

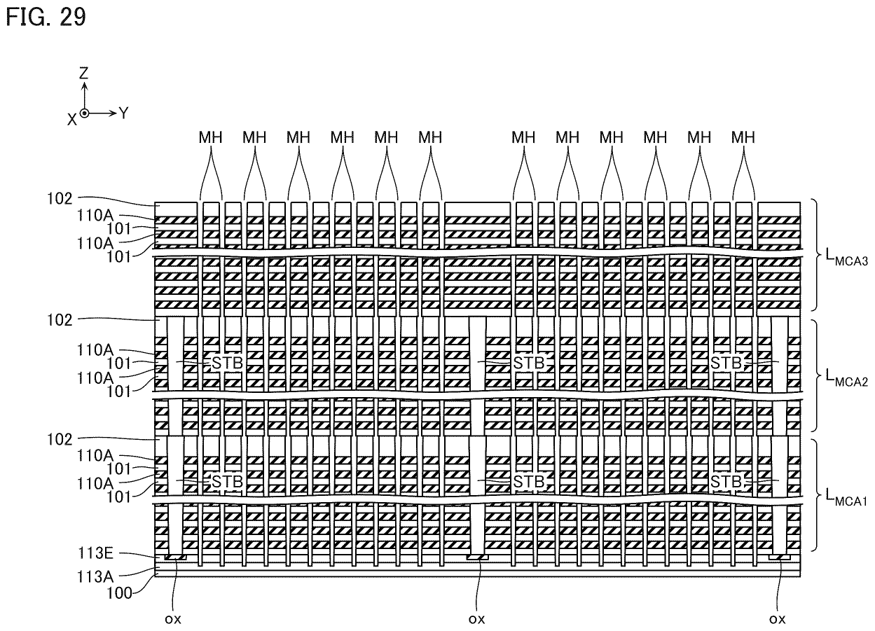

Next, as shown in FIG. 29, for example, the sacrifice films 120A provided at the height positions corresponding to the memory cell array layers L_{MCA1}, L_{MCA2} are removed. This step is performed by the likes of wet etching, for example.

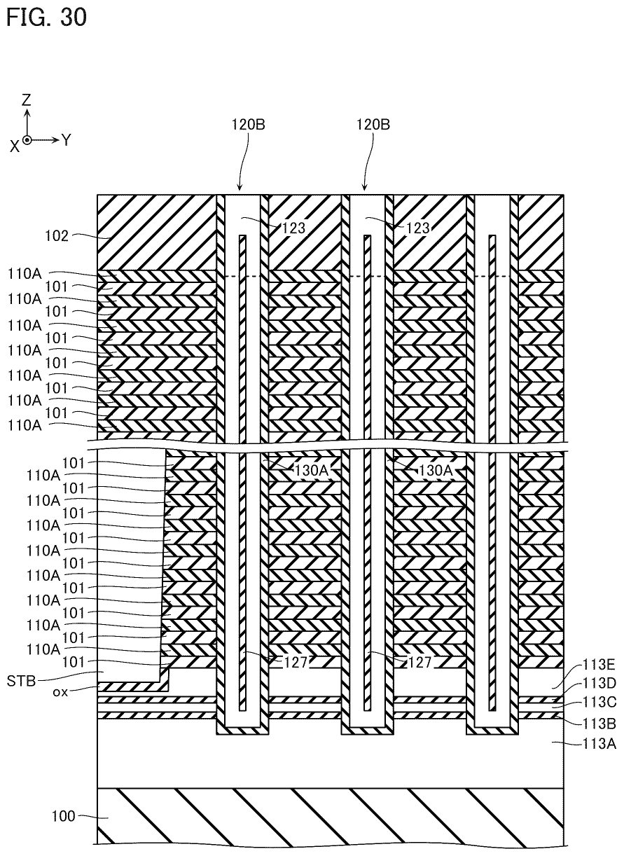

Next, as shown in FIG. 30, for example, insulating films 130A, semiconductor columns 120B, and the insulating columns 127 are formed inside the memory holes MH, at the height positions corresponding to the memory cell array layers L_{MCA1}, L_{MCA2}, L_{MCA3}. The insulating film 130A is basically configured similarly to the gate insulating film 130, but covers an outer peripheral surface of the semiconductor column 120B at the height positions of the sacrifice layers 113B, 113C, 113D, too. The semiconductor column 120B is basically configured similarly to the semiconductor column 120, but does not have formed in its lower end portion the region 121 including an N-type impurity. This step is performed by a method such as CVD, for example.

Next, though illustration of the following is omitted, a part of the insulating layer 102 corresponding to the memory cell array layer L_{MCA3} is formed. This step causes an upper surface of the structure inside the memory hole MH (the insulating film 130A, the semiconductor column 120B, and the insulating column 127) to be covered by the part of the insulating layer 102. This step is performed by a method such as CVD, for example.

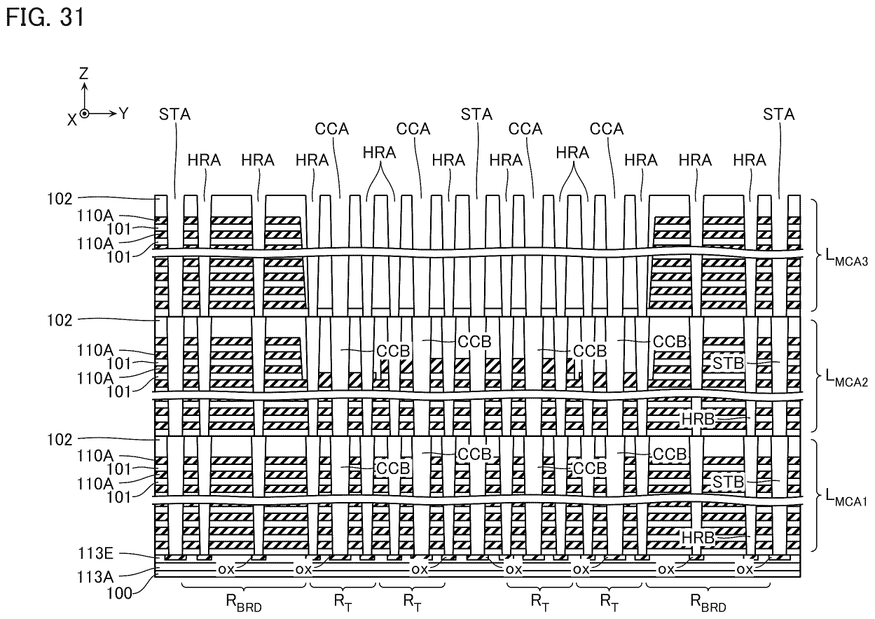

Next, as shown in FIG. 31, for example, via holes HRA are formed at positions corresponding to the support insulating columns HR. Moreover, contact holes CCA are formed at positions corresponding to the contact electrodes CC. Moreover, trenches STA are formed at positions corresponding to the inter-finger structures ST. These via holes HRA, contact holes CCA, and trenches STA extend in the Z-direction, penetrate the insulating layer 102 and the insulating layers 101 and sacrifice layers 110A corresponding to the memory cell array layer L_{MCA3}, and expose upper ends of the sacrifice films HRB, CCB, STB provided at the height position corresponding to the memory cell array layer L_{MCA2}. This step is performed by a method such as RIE, for example.

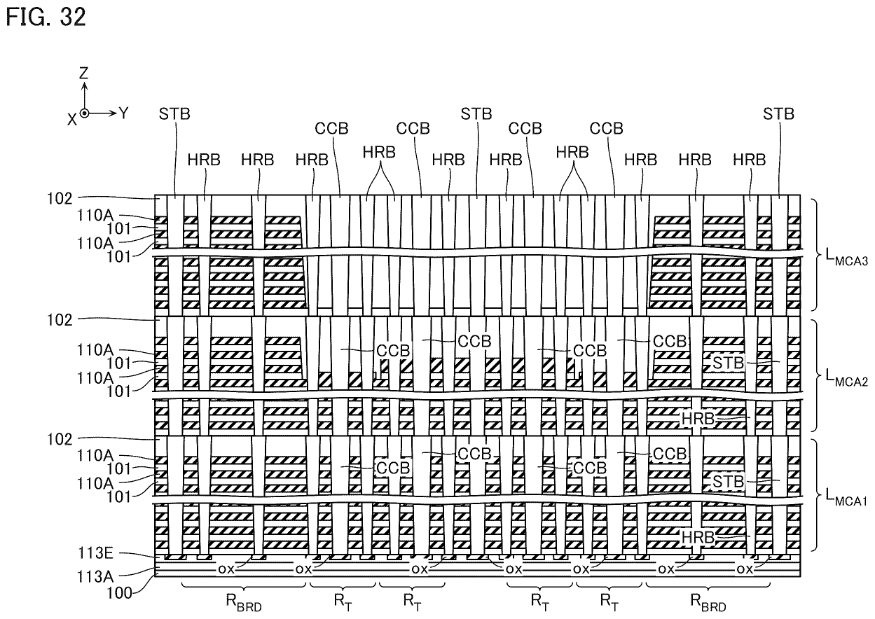

Next, as shown in FIG. 32, for example, sacrifice films HRB, CCB, STB of the likes of polycrystalline silicon are formed in the via holes HRA, the contact holes CCA, and the trenches STA, at the height position corresponding to the memory cell array layer L_{MCA3}. This step is performed by a method such as CVD, for example.

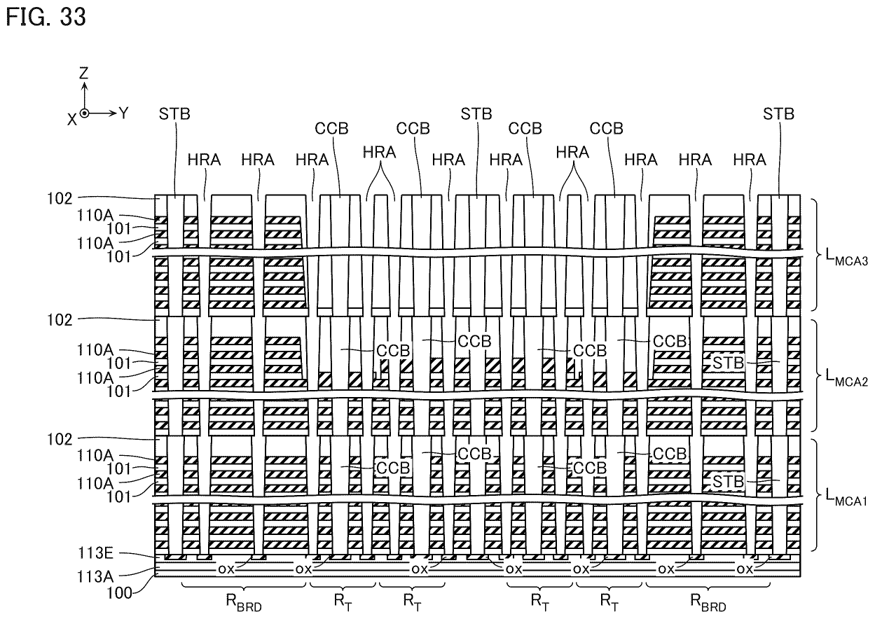

Next, as shown in FIG. 33, for example, the sacrifice films HRB provided at the height positions corresponding to the memory cell array layers L_{MCA1}, L_{MCA2}, L_{MCA3} are removed. This step is performed by a method such as wet etching, for example.

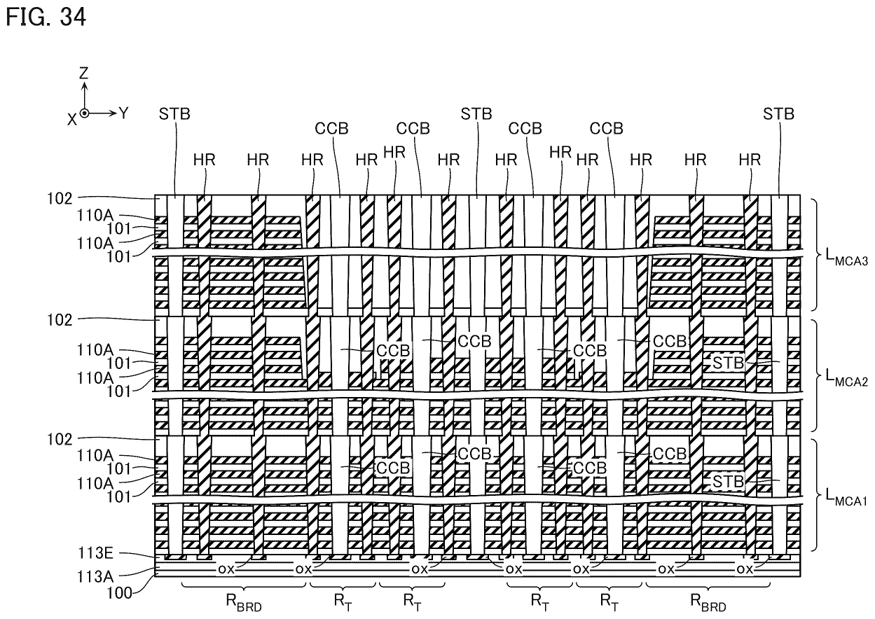

Next, as shown in FIG. 34, for example, the support insulating columns HR are formed in the via holes HRA at the height positions corresponding to the memory cell array layers L_{MCA1}, L_{MCA2}, L_{MCA3}. This step is performed by a method such as CVD, for example.

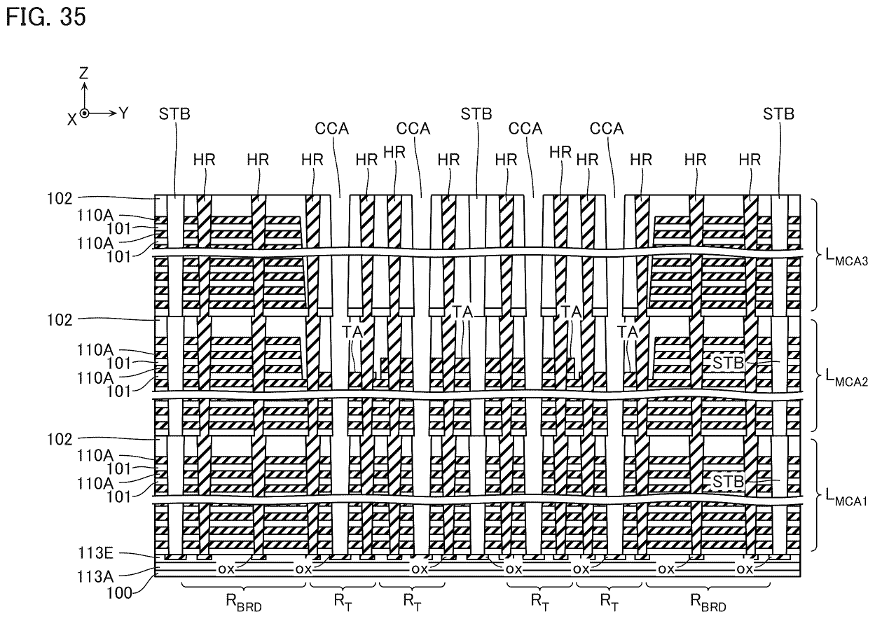

Next, as shown in FIGS. 35 and 36, for example, the sacrifice films CCB provided at the height positions corresponding to the memory cell array layers L_{MCA1}, L_{MCA2}, L_{MCA3} are removed. This step is performed by a method such as wet etching, for example.

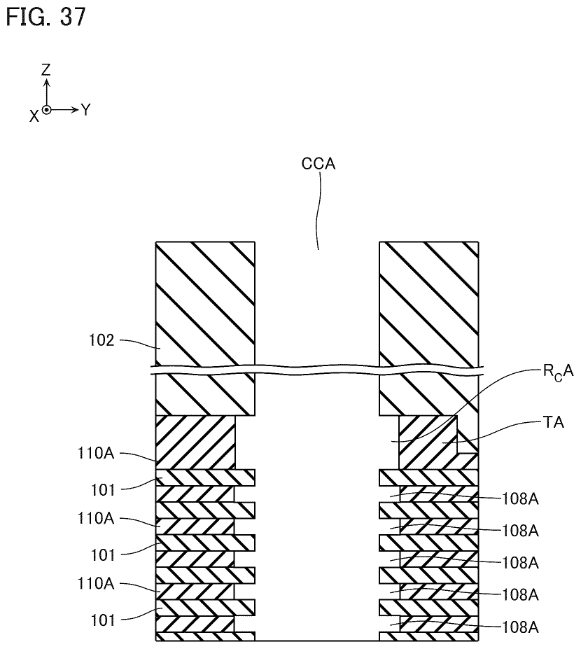

Next, as shown in FIG. 37, for example, parts of the sacrifice layers 110A are removed on the inner peripheral surface of the contact hole CCA. As a result, a plurality of recesses 108A are formed at positions corresponding to the plurality of insulating layers 108. Moreover, a recess R_{C}A is formed at a position corresponding to the connecting region R_{C} (FIG. 10). This step is performed by the likes of wet etching, for example.

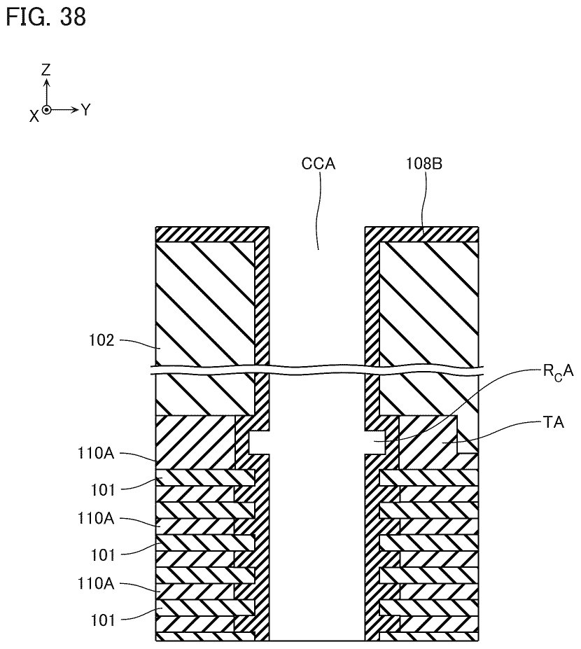

Next, as shown in FIG. 38, for example, an insulating layer 108B is formed on an upper surface of the insulating layer 102 corresponding to the memory cell array layer L_{MCA3}, and on the inner peripheral surfaces of the plurality of contact holes CCA. At this time, film thickness of the insulating layer 108B is greater than half the size of thickness in the Z-direction of the sacrifice layer 110A. Hence, the recesses 108A are filled in by the insulating layer 108B. On the other hand, film thickness of the insulating layer 108B is less than half the size of thickness in the Z-direction of the terrace portion TA of the sacrifice layer 110A. Hence, the recess R_{C}A is not filled in by the insulating layer 108B.

Moreover, film thickness of the insulating layer 108B is less than radius of the contact hole CCA. Hence, the contact hole CCA is not filled in by the insulating layer 108B either. This step is performed by a method such as CVD, for example.

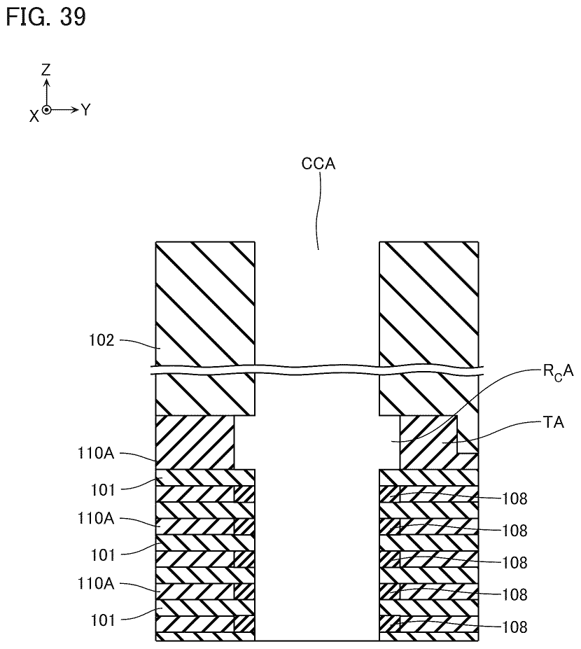

Next, as shown in FIG. 39, for example, a part of the insulating layer 108B is removed. In this step, portions formed on the upper surface of the insulating layer 102 corresponding to the memory cell array layer L_{MCA3}, and on a side surface of the insulating layer 102, side surfaces of the plurality of insulating layers 101, and a side surface of the terrace portion TA of the sacrifice layer 110A, of the insulating layer 108B are removed. As a result, the upper surface of the insulating layer 102, side surface of the insulating layer 102, side surfaces of the plurality of insulating layers 101, and side surface of the terrace portion TA of the sacrifice layer 110A are exposed inside the contact hole CCA. This step is performed by the likes of wet etching, for example. In this step, the plurality of insulating layers 108 are formed at positions corresponding to the plurality of recesses 108A.

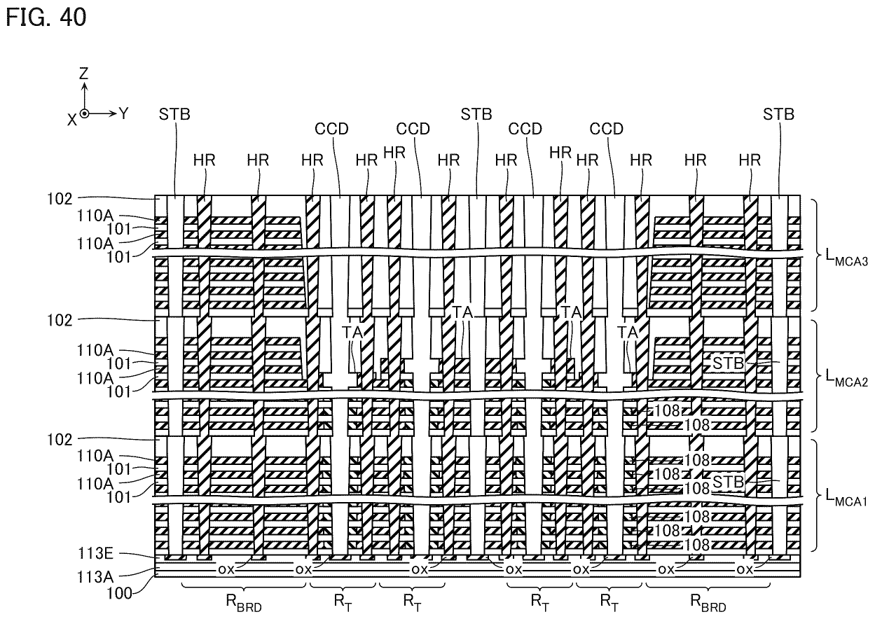

Next, as shown in FIG. 40, for example, sacrifice layers CCD are formed inside the contact holes CCA at the height positions corresponding to the memory cell array layers L_{MCA1}, L_{MCA2}, L_{MCA3}. This step is performed by a method such as CVD, for example.

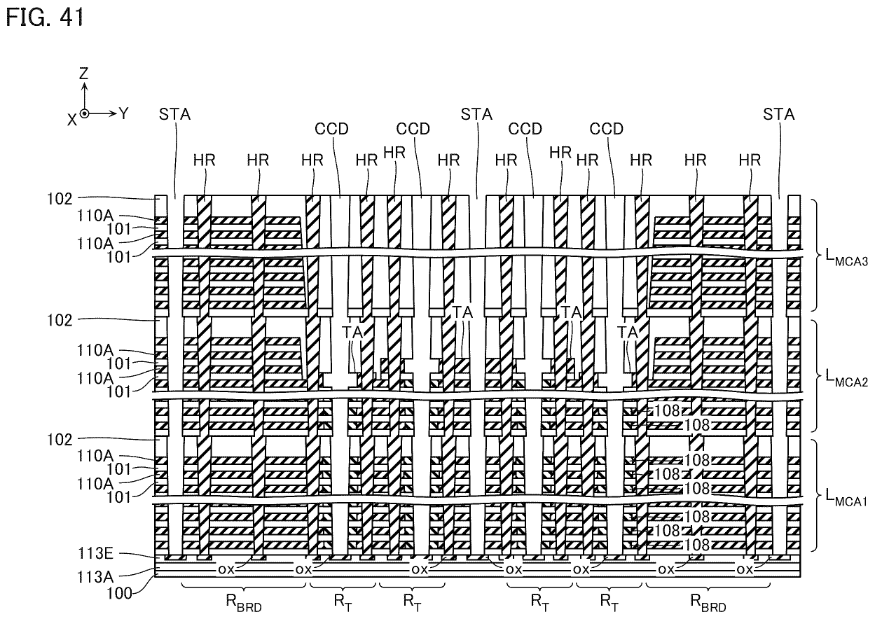

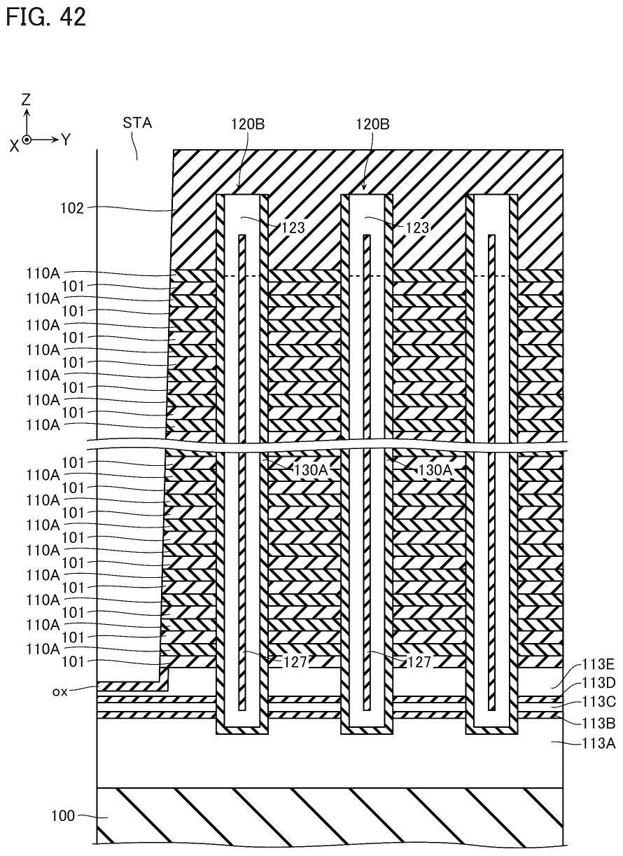

Next, as shown in FIGS. 41 and 42, for example, the sacrifice films STB provided at height positions corresponding to the memory cell array layers L_{MCA1}, L_{MCA2}, L_{MCA3} are removed. This step is performed by a method such as wet etching, for example.

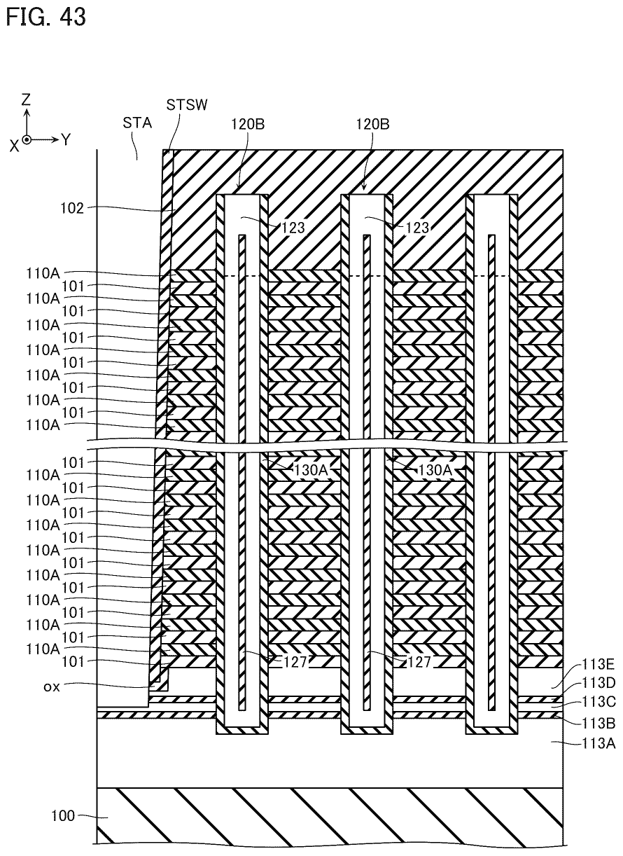

Next, as shown in FIG. 43, for example, a protective film STSW is formed on an inner wall surface and bottom surface of the trench STA, by a method such as CVD. Moreover, the protective film STSW, the oxide layer ox, semiconductor layer 113E, and sacrifice layer 113D are removed at the bottom surface of the trench STA, by a method such as RIE, to expose the sacrifice layer 113C.

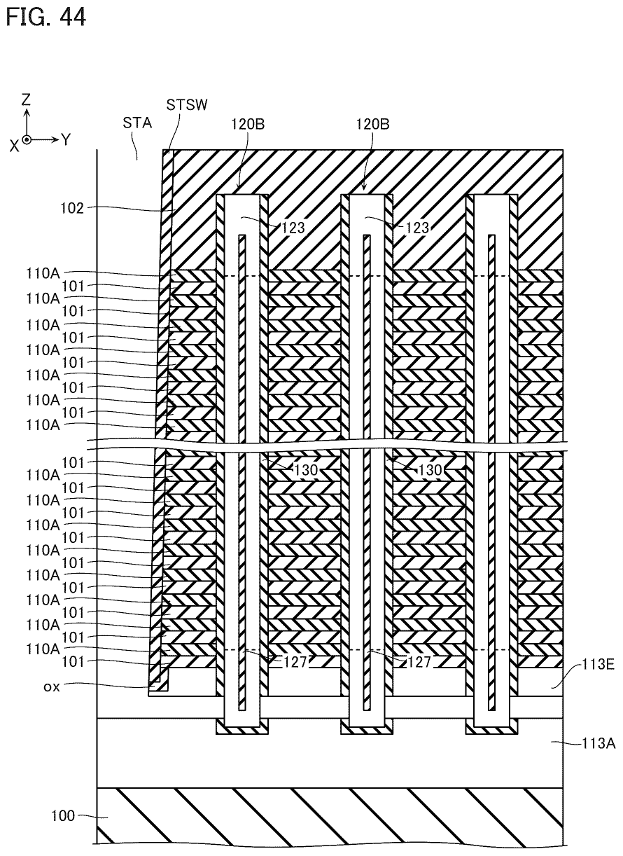

Next, as shown in FIG. 44, for example, the sacrifice layer 113B, sacrifice layer 113C, sacrifice layer 113D, and parts of the gate insulating films 130A are removed. This step is performed by a method such as wet etching, for example. Note that in this step, the gate insulating film 130 is formed.

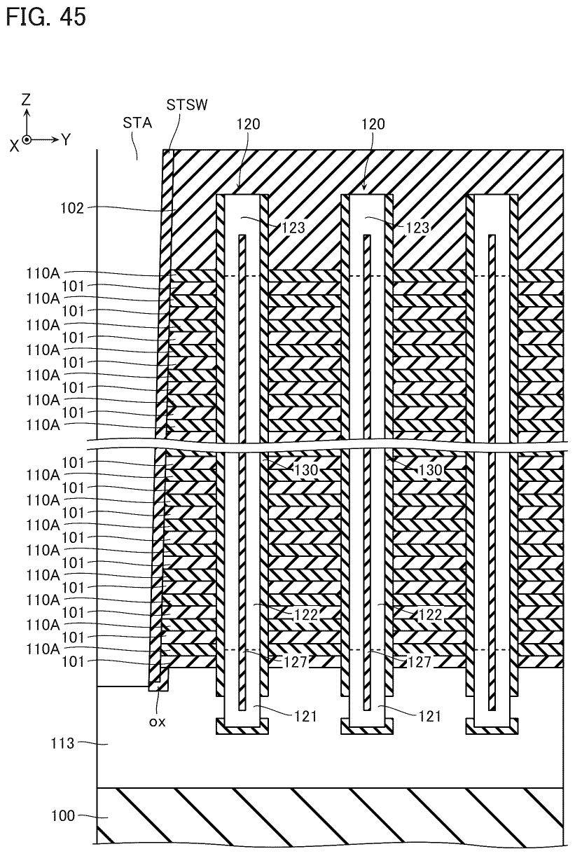

Next, as shown in FIG. 45, for example, the conductive layer 113 is formed. This step is performed by a method such as epitaxial growth, for example. In this step, an N-type impurity is diffused into the lower end portion of the semiconductor columns 120B, whereby the semiconductor columns 120 are formed.

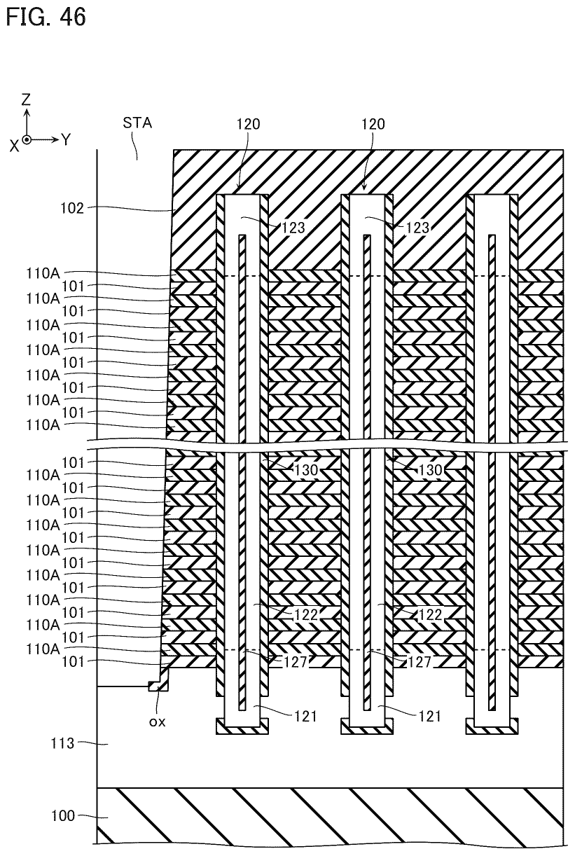

Next, as shown in FIG. 46, for example, the protective film STSW is removed. This step is performed by a method such as wet etching, for example.

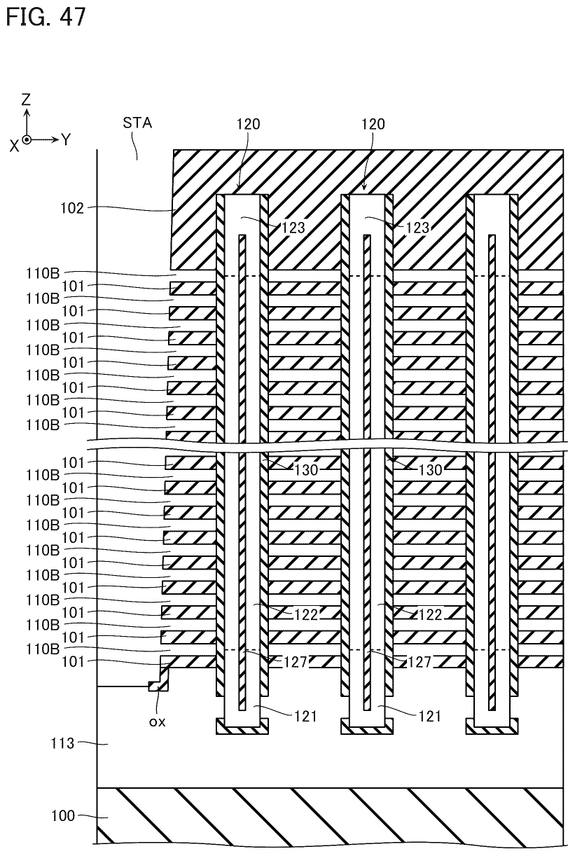

Next, as shown in FIG. 47, for example, the sacrifice layers 110A are removed via the trench STA, and a plurality of cavities 110B are formed. This results in there being formed a hollow structure including: the plurality of insulating layers 101 and insulating layer 102 arranged in the Z-direction; and the structures in the memory holes MH (the semiconductor columns 120, the gate insulating films 130, and the insulating columns 127), and support insulating columns HR that support these insulating layers 101 and insulating layer 102. This step is performed by a method such as wet etching, for example.

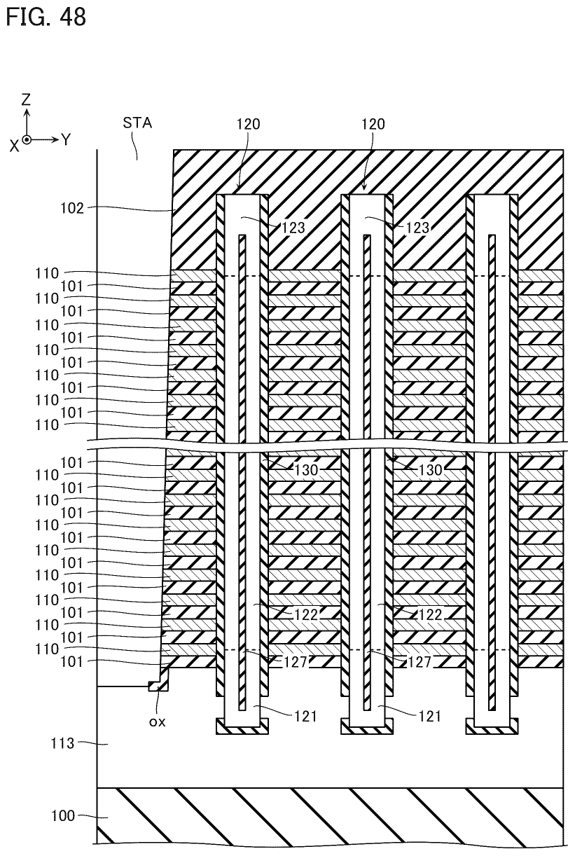

Next, as shown in FIG. 48, for example, the conductive layers 110 are formed in the cavities 110B. This step is performed by a method such as CVD, for example. Note that in this step, the high-dielectric-constant insulating films 104 described with reference to FIG. 5 are formed before the conductive layers 110 are formed.

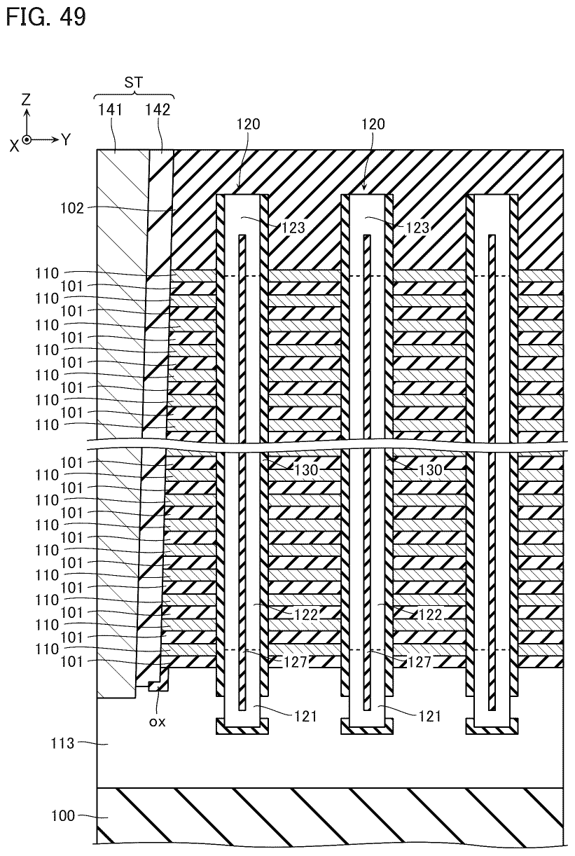

Next, as shown in FIG. 49, for example, the inter-finger structure ST is formed in the trench STA. This step is performed by methods such as CVD and RIE, for example.

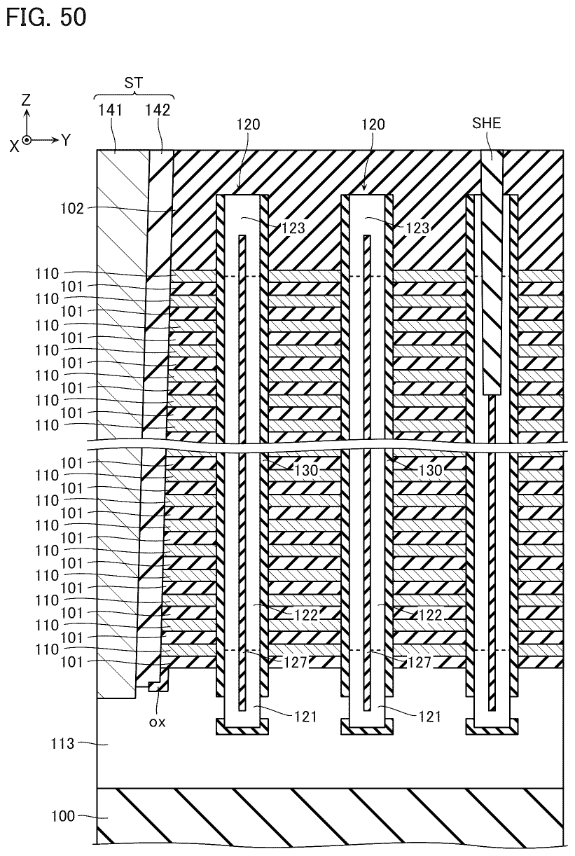

Next, as shown in FIG. 50, for example, the inter-string unit insulating member SHE is formed. This step is performed by methods such as RIE and CVD, for example.

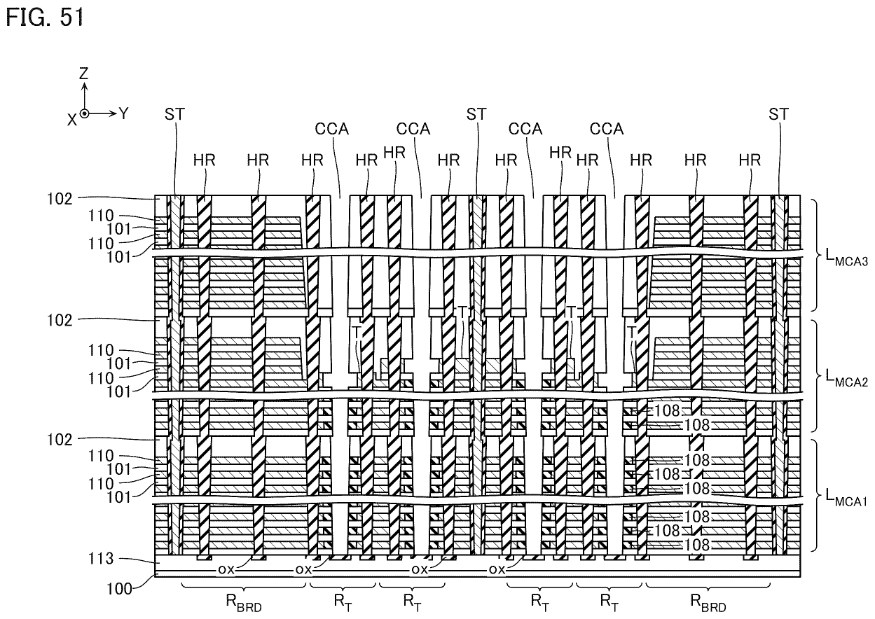

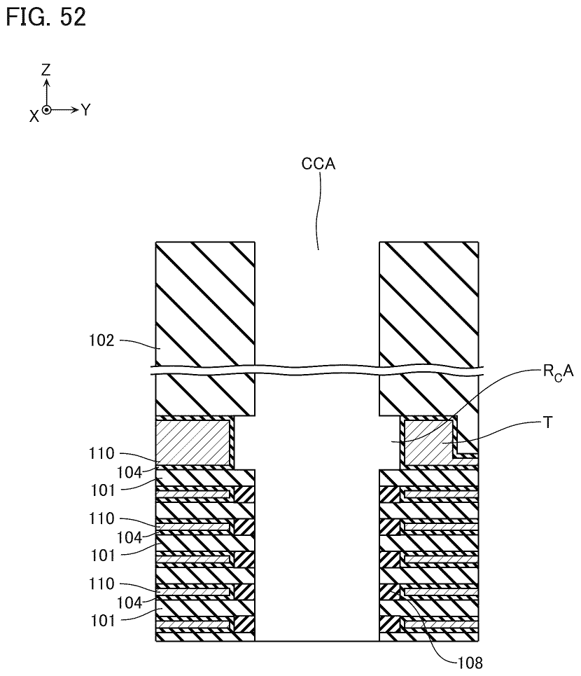

Next, as shown in FIGS. 51 and 52, for example, the sacrifice films CCD are removed. This step is performed by a method such as wet etching, for example.

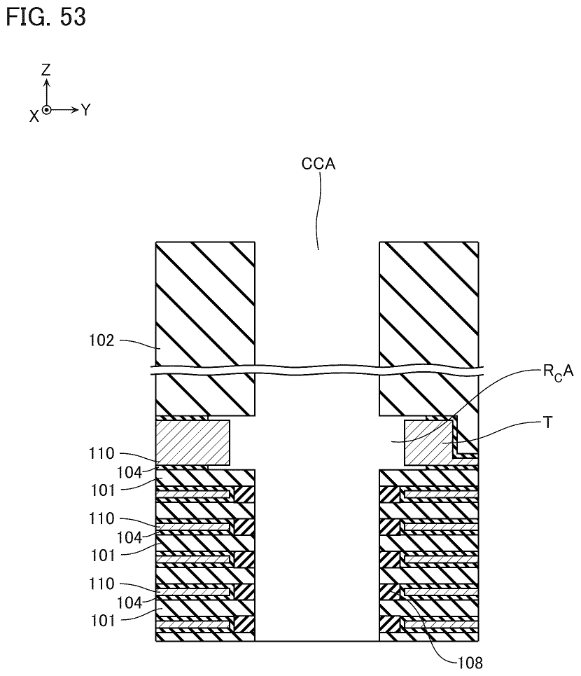

Next, as shown in FIG. 53, for example, a part of the high dielectric-constant insulating film 104 is removed in the recess R_{C}A. As a result, the side surface of the conductive layer 110 is exposed in the recess R_{C}A. This step is performed by a method such as wet etching, for example.

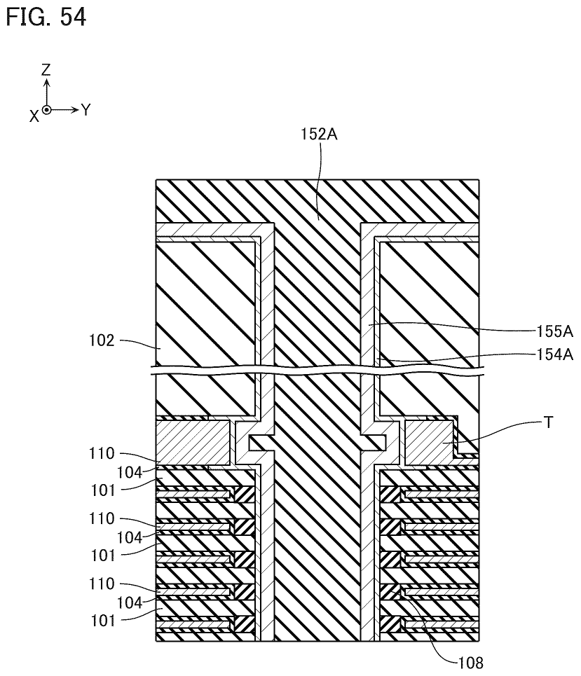

Next, as shown in FIG. 54, for example, a barrier conductive film 154A, a metal film 155A, and an insulating layer 152A are formed on the upper surface of the insulating layer 102 corresponding to the memory cell array layer L_{MCA3} and inside the contact hole CCA provided at the height positions corresponding to the memory cell array layers L_{MCA1}, L_{MCA2}, L_{MCA3}. This step is performed by a method such as CVD, for example. Formation of the metal film 155A is performed by a method such as CVD using tungsten hexafluoride (WF₆), for example.

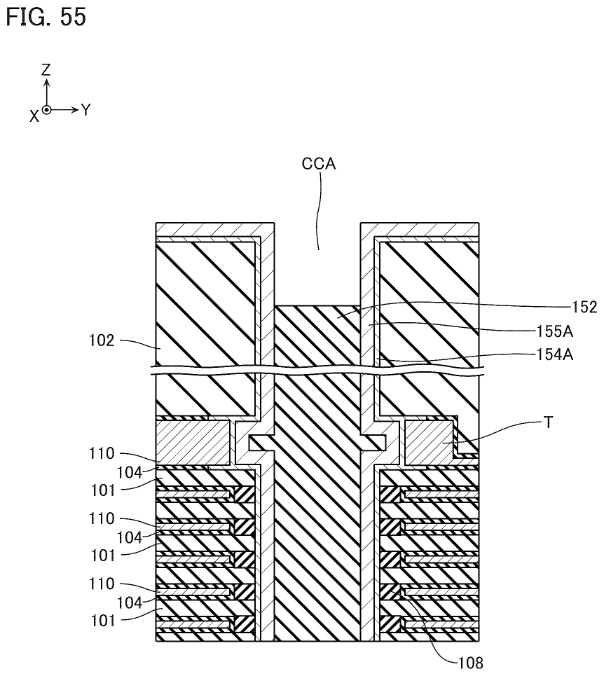

Next, as shown in FIG. 55, for example, a portion covering the upper surface of the insulating layer 102 corresponding to the memory cell array layer L_{MCA3} and portion located in a region closely adjacent to the upper end of the contact hole CCA, of the insulating layer 152A, are removed. This step causes the insulating column 152 to be formed. This step is performed by a method such as RIE, for example.

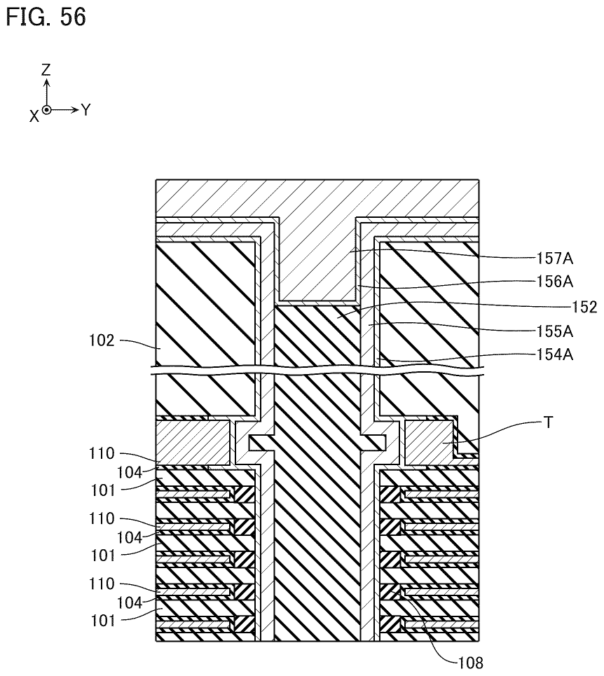

Next, as shown in FIG. 56, for example, a barrier conductive film 156A and a metal film 157A are formed on an upper surface and inner peripheral surface of the metal film 155A, above the insulating layer 102 corresponding to the memory cell array layer L_{MCA3} and in the region closely adjacent to the upper end of the contact hole CCA corresponding to the memory cell array layer L_{MCA3}. This step is performed by a method such as CVD, for example.

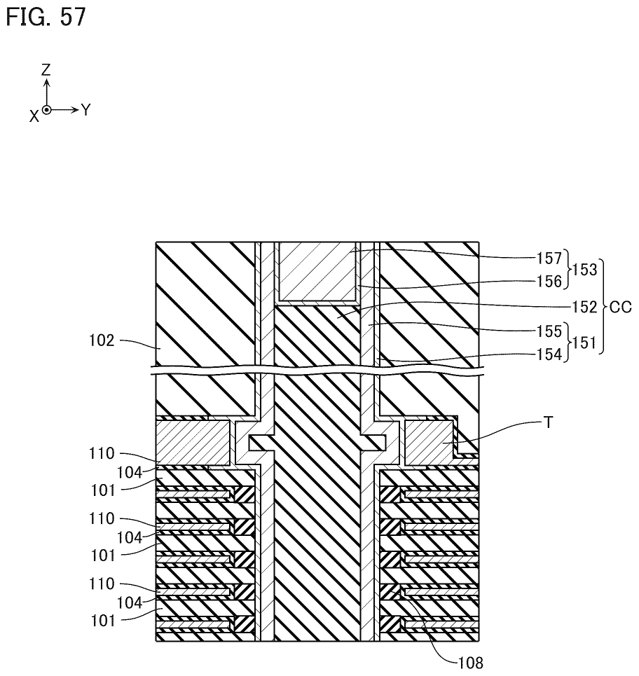

Next, as shown in FIG. 57, for example, parts of the barrier conductive film 154A, metal film 155A, barrier conductive film 156A, and metal film 157A are removed to expose the upper surface of the insulating layer 102 corresponding to the memory cell array layer L_{MCA3}. This step causes the contact electrode CC to be formed. This step is performed by a method such as CMP, for example.

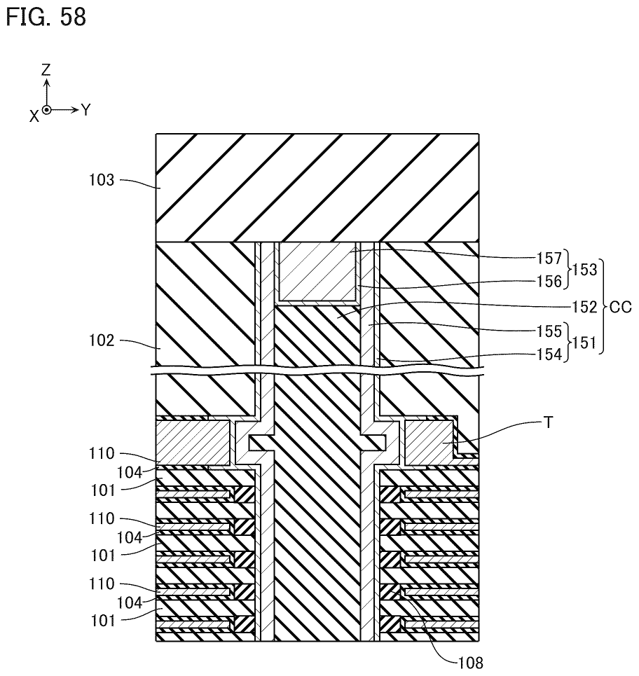

Next, as shown in FIG. 58, for example, the insulating layer 103 is formed on upper surfaces of the insulating layer 102 corresponding to the memory cell array layer L_{MCA3} and the contact electrode CC. This step is performed by the likes of CVD, for example.

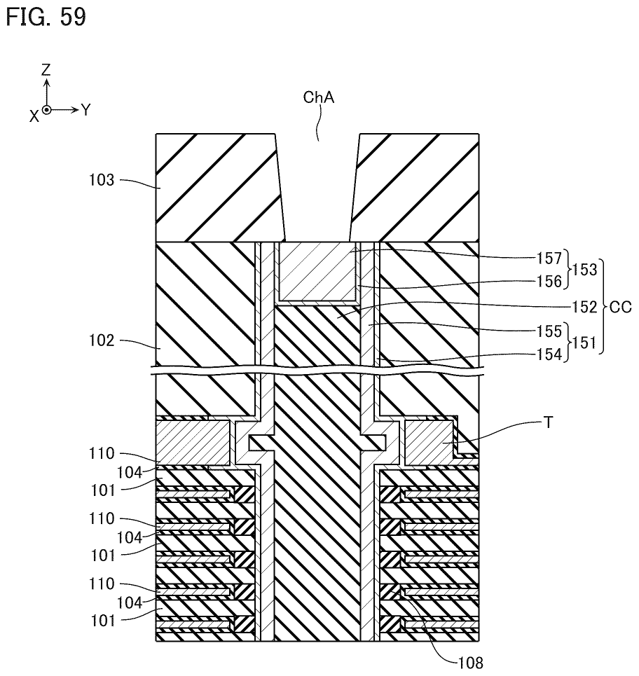

Next, as shown in FIG. 59, for example, a contact hole ChA is formed at a position corresponding to the contact electrode Ch. The contact hole ChA extends in the Z-direction, penetrates the insulating layer 103, and exposes an upper surface of the contact electrode CC, for example, an upper surface of the metal film 157. This step is performed by a method such as RIE, for example.

Subsequently, the contact electrode Ch is formed inside the contact hole ChA, whereby a structure of the kind shown in FIG. 10 is formed. Moreover, the bit lines BL, and so on, are formed, whereby the semiconductor memory device according to the first embodiment is formed.

### [Advantages]

With increasingly high levels of integration of semiconductor memory devices, the number of conductive layers 110 (FIG. 4) arranged in the Z-direction is increasing. As a result, aspect ratio (the ratio of a length in the Z-direction with respect to a diameter in an XY cross section) of the contact electrode CC is also increasing. In order for a contact electrode CC of large aspect ratio to be formed, it is conceivable that a contact hole of large aspect ratio be formed by a method such as RIE, and that a metal film be formed by a method such as CVD, inside this contact hole, for example.

Now, in the method of manufacturing according to the first embodiment, the contact holes CCA are formed in steps performed on three occasions, namely, in the step described with reference to FIG. 12, the step described with reference to FIG. 22, and the step described with reference to FIG. 31. This kind of method is more easily realizable than when a contact hole of large aspect ratio is formed on a single occasion.

Note that when this kind of method is adopted, the contact holes CCA formed in the step described with reference to FIG. 12, the step described with reference to FIG. 22, and the step described with reference to FIG. 31 will sometimes be each formed in shapes whose diameters increase from their lower end portions upwards, for example. This may result in the contact electrode CC according to the present embodiment comprising three tiered portions cc₁, cc₂, cc₃ (FIG. 9) whose diameters increase from their lower side to their upper side.

Moreover, in the present embodiment, the contact electrode CC connected to the conductive layer 110 contacts the conductive layer 110 not at the contact electrode CC's lower end, but at the connecting region R_{C} formed between its upper end and lower end.

Now, in order for a contact electrode connected at the lower end to the conductive layer 110 to be formed, it is conceivable that a contact hole be formed after formation of the conductive layer 110, and that the terrace portion T of the conductive layer 110 be utilized as an etching stopper, for example. However, height positions of the plurality of terrace portions T corresponding to the plurality of conductive layers 110, all differ. Therefore, in this kind of method, the upper surface of a comparatively upwardly located terrace portion T will be exposed in the bottom of the contact hole at a comparatively early stage after formation of the contact hole is started. Such a terrace portion T will continue to be subjected to gas of RIE during a period up until the upper surface of a comparatively downwardly located terrace portion T is exposed in the bottom of the contact hole. As a result, there is concern that the contact hole will penetrate the terrace portion T. There is consequently a risk that two or more conductive layers 110 arranged in the Z-direction will be short-circuited via the contact electrode.

In this respect, the contact electrode CC according to the first embodiment, which adopts a structure premised on the contact hole CCA penetrating a plurality of conductive layers 110 during manufacturing, enables inter-conductive layer 110 short-circuiting via the contact electrode CC to be suppressed.

Note that as a result of such a structure having been adopted, as described with reference to FIG. 10, the contact electrode CC according to the present embodiment will comprise: the connecting region R_{C} contacting the conductive layer 110; the lead-out region R_{L} provided above the connecting region R_{C}; and the through region R_{TH} provided below the connecting region R_{C}. Moreover, the width W_{RC154} of the contact electrode CC in the connecting region R_{C} will be greater than the widths W_{RL154}, W_{RTH154} of the contact electrode CC in the lead-out region R_{L} and through region R_{TH}.

Now, when, for example, it is attempted to fill in the contact hole CCA with the metal film 155A, without the insulating layer 152A being formed, in the step described with reference to FIG. 54, then there is a possibility that a void will be formed inside the contact hole CCA. For example, it is conceivable that since the contact electrode CC according to the present embodiment includes the three tiered portions cc₁, cc₂, cc₃ (FIG. 9) whose diameters increase from their lower side to their upper side, voids will be formed inside the tiered portions cc₁, cc₂, due to the contact hole CCA being blocked at lower end portions of the tiered portions cc₂, cc₃, and gas of CVD ceasing to be supplied inside the tiered portions cc₁, cc₂. Moreover, it is conceivable that when positions of the contact holes CCA formed in each of steps described with reference to FIGS. 12, 22, and 31 get misarranged a certain amount or more, then even when diameters of the three tiered portions cc₁, cc₂, cc₃ do not increase from their lower side to their upper side, the contact hole CCA will be blocked at a boundary portion of the tiered portions cc₃, cc₂ or boundary portion of the tiered portions cc₂, cc₁, and voids will be formed inside the tiered portions cc₁, cc₂. Furthermore, it is conceivable too that, for example, since the connecting region R_{C} has a comparatively large volume, the lead-out region R_{L} will be filled in by the metal film 155A before this portion is filled in, and a void will be formed inside the connecting region R_{C}.

Now, when formation of the metal film 155A is performed by a method such as CVD using tungsten hexafluoride (WF₆) as described with reference to FIG. 54, fluorine gas remains in a void inside the contact hole CCA. This may result in a part of the insulating layer 101 being removed, and leading to a lowering of insulation between two conductive layers 110 arranged in the Z-direction.

Accordingly, in the present embodiment, in the step described with reference to FIG. 54, the contact hole CCA is filled in by the insulating layer 152A, not the metal film 155A. Due to such a method, it is possible for remaining of fluorine gas to be suppressed, even when a void has been formed inside the contact hole CCA. It is therefore possible for lowering of insulation between two conductive layers 110 arranged in the Z-direction to be suitably suppressed.

Moreover, in the present embodiment, in the steps described with reference to FIGS. 55 to 57, the conductive member 153 is formed on the upper portion of the insulating column 152. Due to such a configuration, it is possible for the upper surface of the contact electrode CC to be exposed in the bottom surface of the contact hole ChA, and for the contact electrode Ch and contact electrode CC to be thereby suitably connected, in the step described with reference to FIG. 59.

Moreover, in the present embodiment, the outer peripheral surface of the conductive member 153 contacts the inner peripheral surface of the conductive member 151. Due to such a configuration, it is possible for area of the portion contacting the metal film 157 via the barrier conductive film 156, of the metal film 155 to be broadened. This makes it possible for a low resistance contact electrode CC to be formed.

### Second Embodiment

The contact electrode CC according to the first embodiment comprises: the conductive member 151 extending in the Z-direction; the insulating column 152 which extends in the Z-direction, and has the outer peripheral surface covered by the conductive member 151; and the conductive member 153 which is provided in the upper end portion of the contact electrode CC, and has the outer peripheral surface contacting the conductive member 151. Moreover, the conductive member 151 comprises the barrier conductive film 154 and the metal film 155, and the conductive member 153 comprises the barrier conductive film 156 and the metal film 157.

However, such a configuration is merely an exemplification, and film configurations of the conductive member 151, the insulating column 152, and the conductive member 153 are appropriately adjustable. A contact electrode CC2 having a different film configuration from the contact electrode CC will be described below as a second embodiment.

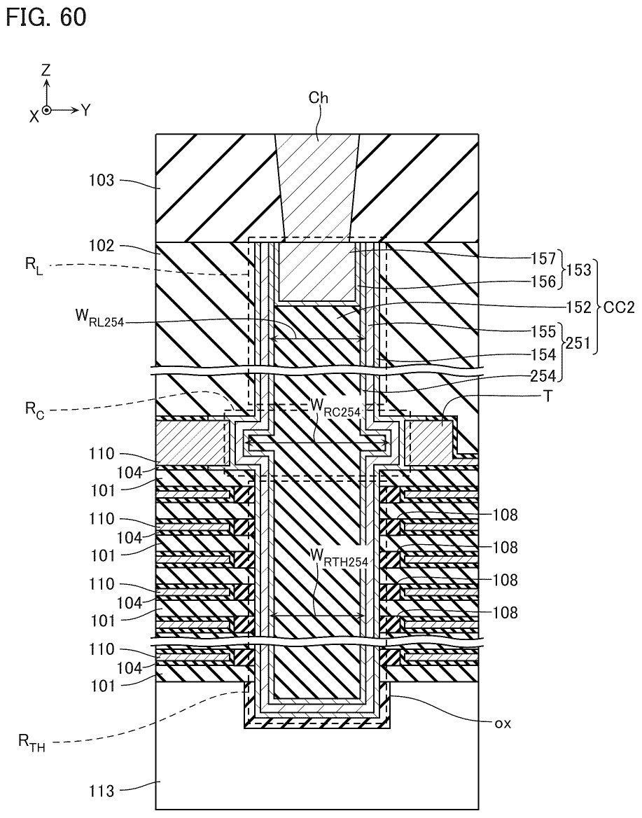

FIG. 60 is a schematic cross-sectional view of a semiconductor memory device according to the second embodiment. In the following description, configurations similar to in the first embodiment will be assigned with the same symbols as in the first embodiment, and descriptions thereof omitted.

The semiconductor memory device according to the second embodiment is basically configured similarly to the semiconductor memory device according to the first embodiment. However, the semiconductor memory device according to the second embodiment comprises the contact electrode CC2 instead of the contact electrode CC.

The contact electrode CC2 according to the second embodiment is basically configured similarly to the contact electrode CC according to the first embodiment.

However, the contact electrode CC2 comprises a conductive member 251 instead of the conductive member 151.

The conductive member 251 is basically configured similarly to the conductive member 151. However, the conductive member 251 further comprises a barrier conductive film 254, in addition to the barrier conductive film 154 and metal film 155. The barrier conductive film 254 extends in the Z-direction, has an outer peripheral surface and lower end portion covered by the metal film 155, and contacts the metal film 155. The barrier conductive film 254 may include the likes of titanium nitride (TiN) or tantalum nitride (TaN), for example. The barrier conductive film 254 extends in the Z-direction over the lead-out region R_{L}, the connecting region R_{C}, and the through region R_{TH} (refer to FIG. 9).

Portions provided in the lead-out region R_{L}, connecting region R_{C}, and through region R_{TH}, of the barrier conductive film 254 are each formed in a substantially cylindrical shape. In FIG. 60, a width in the X-direction and the Y-direction (a diameter in an XY cross section) of the portion provided in the connecting region R_{C}, of the barrier conductive film 254 is indicated as a width W_{RC254}. Similarly, a width in the X-direction and the Y-direction (a diameter in an XY cross section) of the portion provided in the lead-out region R_{L}, of the barrier conductive film 254 is indicated as a width W_{RL254}. Similarly, a width in the X-direction and the Y-direction (a diameter in an XY cross section) of the portion provided in the through region R_{TH}, of the barrier conductive film 254 is indicated as width W_{RTH254}. The width W_{RC254} is greater than the widths W_{RL254}, W_{RTH254}.

Note that in the second embodiment, the lower end portion and the outer peripheral surface of the insulating column 152 contact the conductive member 251 (more specifically, the barrier conductive film 254).

The present embodiment too enables similar advantages to those of the semiconductor memory device according to the first embodiment. Moreover, this kind of configuration enables risk of abnormal oxidation of the metal film 155 due to oxygen in the insulating column 152 to be suppressed.

### Third Embodiment

As mentioned above, film configurations of the conductive member 151, the insulating column 152, and the conductive member 153 are appropriately adjustable. The second embodiment has described an example where the contact electrode CC2 comprises the conductive member 251 having a different film configuration from the conductive member 151 of the contact electrode CC. A contact electrode CC3 having a film configuration that further differs from that of the contact electrode CC will be described below as a third embodiment.

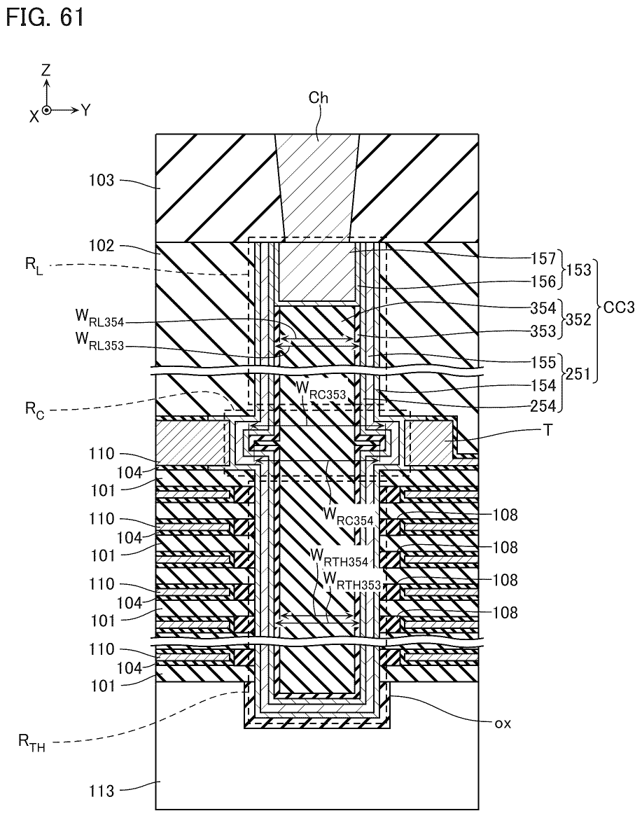

FIG. 61 is a schematic cross-sectional view of a semiconductor memory device according to the third embodiment. In the following description, configurations similar to in the second embodiment will be assigned with the same symbols as in the second embodiment, and descriptions thereof omitted.

The semiconductor memory device according to the third embodiment is basically configured similarly to the semiconductor memory device according to the second embodiment. However, the semiconductor memory device according to the third embodiment comprises the contact electrode CC3 instead of the contact electrode CC2.

The contact electrode CC3 according to the third embodiment is basically configured similarly to the contact electrode CC2 according to the second embodiment. However, the contact electrode CC3 comprises an insulating column 352 instead of the insulating column 152.

An upper end portion of the insulating column 352 is covered by the conductive member 153, and contacts the conductive member 153 (more specifically, the barrier conductive film 156). A lower end portion and an outer peripheral surface of the insulating column 352 are covered by the conductive member 251, and contact the conductive member 251 (more specifically, the barrier conductive film 254).

As shown in FIG. 61, for example, the insulating column 352 comprises: a barrier insulating film 353 extending in the Z-direction; and an insulating film 354 which extends in the Z-direction, has an outer peripheral surface and lower end portion covered by the barrier insulating film 353, and contacts the barrier insulating film 353. The barrier insulating film 353 may include the likes of silicon nitride (SiN), for example. The insulating film 354 may include the likes of silicon oxide (SiO₂), for example. The barrier insulating film 353 and the insulating film 354 extend in the Z-direction over the lead-out region R_{L}, the connecting region R_{C}, and the through region R_{TH}.

Portions provided in the lead-out region R_{L}, the connecting region R_{C}, and the through region R_{TH}, of the barrier insulating film 353 are each formed in a substantially cylindrical shape. Portions provided in the lead-out region R_{L}, the connecting region R_{C}, and the through region R_{TH}, of the insulating film 354 are each formed in a substantially circular column-like shape. In FIG. 61, widths in the X-direction and the Y-direction (diameters in an XY cross section) of the portions provided in the connecting region R_{C}, of the barrier insulating film 353 and the insulating film 354 are respectively indicated as widths W_{RC353}, W_{RC354}. Similarly, widths in the X-direction and the Y-direction (diameters in an XY cross section) of the portions provided in the lead-out region R_{L}, of the barrier insulating film 353 and the insulating film 354 are respectively indicated as widths W_{RL353}, W_{RL354}. Similarly, widths in the X-direction and the Y-direction (diameters in an XY cross section) of the portions provided in the through region R_{TH}, of the barrier insulating film 353 and the insulating film 354 are respectively indicated as widths W_{RTH353}, W_{RTH354}. The width W_{RC353} is greater than the widths W_{RL353}, W_{RTH353}. The width W_{RC354} is greater than the widths W_{RL354}, W_{RTH354}.

The present embodiment too enables similar advantages to those of the semiconductor memory device according to the first embodiment. Moreover, this kind of configuration enables risk of abnormal oxidation of the metal film 155 due to oxygen in the insulating film 354 to be more suitably suppressed.

### Fourth Embodiment

The contact electrode CC according to the first embodiment comprises the connecting region R_{C}, and contacts the conductive layer 110 at the outer peripheral surface of the connecting region R_{C}. However, the film configurations of the kind described in the first through third embodiments are applicable to a variety of contact electrodes. A contact electrode CC4 that contacts the conductive layer 110 at a lower surface of the connecting region R_{C} will be described below as a fourth embodiment.

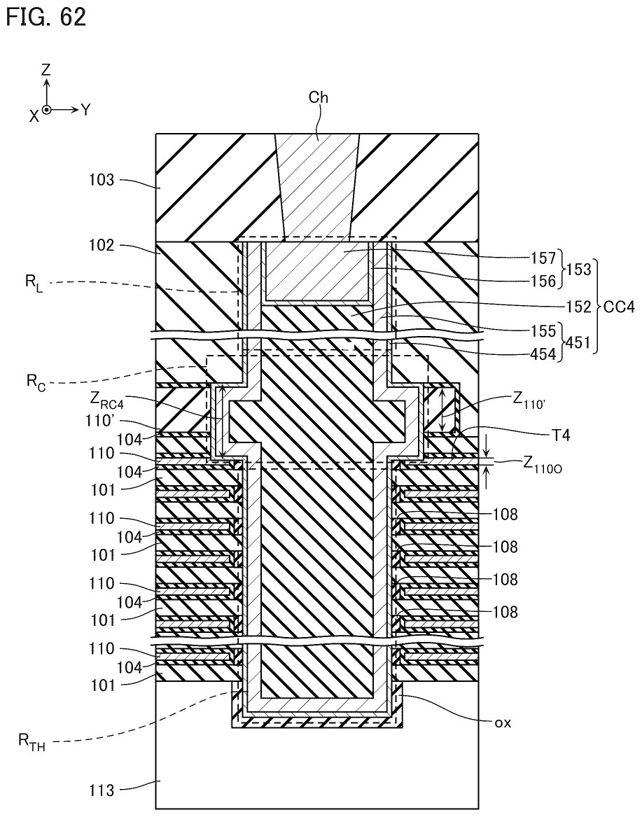

FIG. 62 is a schematic cross-sectional view of a semiconductor memory device according to the fourth embodiment. In the following description, configurations similar to in the first embodiment will be assigned with the same symbols as in the first embodiment, and descriptions thereof omitted.

The semiconductor memory device according to the fourth embodiment is basically configured similarly to the semiconductor memory device according to the first embodiment. However, the semiconductor memory device according to the fourth embodiment comprises the contact electrode CC4 instead of the contact electrode CC.

The contact electrode CC4 according to the fourth embodiment is basically configured similarly to the contact electrode CC according to the first embodiment. However, the contact electrode CC4 comprises a conductive member 451 instead of the conductive member 151.

The conductive member 451 is basically configured similarly to the conductive member 151. However, the conductive member 451 comprises a barrier conductive film 454 instead of the barrier conductive film 154. The barrier conductive film 454 is basically configured similarly to the barrier conductive film 154. However, a portion provided in the connecting region R_{C} of the barrier conductive film 454 is connected to the conductive layer 110 at the portion's lower surface, not at the outer peripheral surface.

Note that in the semiconductor memory device according to the fourth embodiment, the conductive layer 110 is provided with a terrace portion T4 instead of the terrace portion T. The terrace portion T4 is basically configured similarly to the terrace portion T. However, thickness in the Z-direction of the terrace portion T4 is substantially the same as thickness in the Z-direction of another portion of the conductive layer 110.

Moreover, in the semiconductor memory device according to the fourth embodiment, the insulating layer 101 and an insulating member 110′ are provided above the terrace portion T4. The insulating member 110′ includes the likes of silicon oxide (SiO₂), for example. Thickness Z_{110′} in the Z-direction of the insulating member 110′ is less than a length Z_{RC4} in the Z-direction of the connecting region R_{C} of the contact electrode CC4, but greater than thickness Z_{110O} in the Z-direction of the conductive layer 110. An upper surface, a lower surface, and side surfaces in the X-direction and the Y-direction of the insulating member 110′ are provided with the high-dielectric-constant insulating film 104. An outer peripheral surface of a portion provided in the connecting region R_{C} of the barrier conductive film 454 contacts the insulating layer 101 and the insulating member 110′ on the terrace portion T4.

Now, though illustration of the following is omitted, the contact electrode CC4 according to the fourth embodiment also comprises the three tiered portions cc₁, cc₂, cc₃ arranged in the Z-direction (refer to FIG. 9), similarly to the contact electrode CC according to the first embodiment. Hence, the contact electrode CC4 too may have voids formed inside the tiered portions cc₁, cc₂.

Moreover, a width of the contact electrode CC4 in the connecting region R_{C} is greater than a width of the contact electrode CC4 in the lead-out region R_{L} and through region R_{TH}. Such a contact electrode CC4 too may have a void formed in the connecting region R_{C}.

Hence, in the contact electrode CC4 that contacts the conductive layer 110 at the lower surface of the connecting region R_{C}, too, it is possible for remaining of fluorine gas to be suitably suppressed, due to the insulating column 152 being formed inside the conductive member 451. It is therefore possible for lowering of insulation between two conductive layers 110 arranged in the Z-direction to be suitably suppressed.

Moreover, it is possible for the contact electrode Ch and contact electrode CC4 to be suitably connected, due to the conductive member 153 being formed on the upper portion of the insulating column 152.

Moreover, it is possible for a low resistance contact electrode CC4 to be formed, due to the outer peripheral surface of the conductive member 153 contacting the inner peripheral surface of the conductive member 451. Note that the conductive member 451 may further comprise the barrier conductive film 254 described with reference to FIG. 60. Moreover, the contact electrode CC4 may comprise the insulating column 352 described with reference to FIG. 61, instead of the insulating column 152.

### Fifth Embodiment

As mentioned above, the film configurations of the kind described in the first through third embodiments are applicable to a variety of contact electrodes. A contact electrode CC5 connected at its lower end to the conductive layer 110 will be described below as a fifth embodiment.

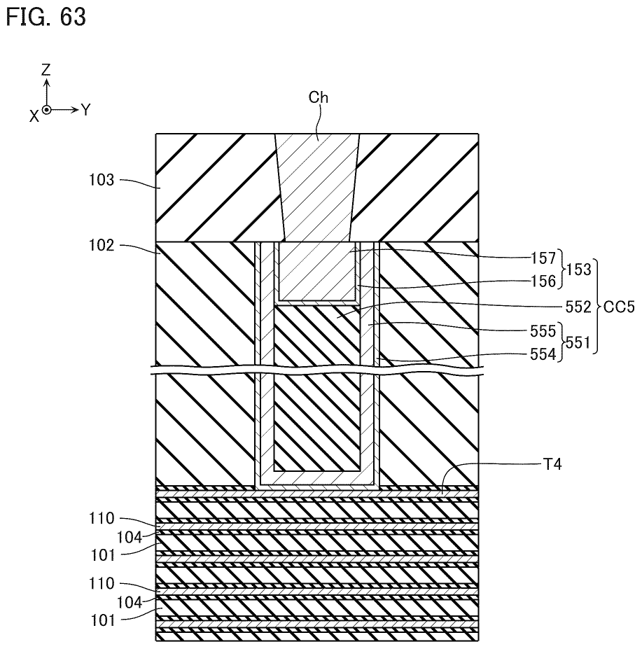

FIG. 63 is a schematic cross-sectional view of a semiconductor memory device according to the fifth embodiment. In the following description, configurations similar to in the first embodiment will be assigned with the same symbols as in the first embodiment, and descriptions thereof omitted.

The semiconductor memory device according to the fifth embodiment is basically configured similarly to the semiconductor memory device according to the first embodiment. However, the semiconductor memory device according to the fifth embodiment comprises the contact electrode CC5 instead of the contact electrode CC. Moreover, the semiconductor memory device according to the fifth embodiment comprises the terrace portion T4 instead of the terrace portion T.

The contact electrodes CC5 are provided corresponding to a plurality of the terrace portions T4. The contact electrode CC5 extends in the Z-direction, is connected at its lower end portion to an upper surface of the terrace portion T4 of a corresponding conductive layer 110, and is connected at its upper end portion to the contact electrode Ch. An outer peripheral surface of the contact electrode CC5 is surrounded by the insulating layer 102.

Though illustration of the following is omitted, those contact electrodes CC5 that correspond to conductive layers 110 in the memory cell array layer L_{MCA1}, of the contact electrodes CC5 comprise the three tiered portions cc₁, cc₂, cc₃ arranged in the Z-direction corresponding to the three memory cell array layers L_{MCA1}, L_{MCA2}, L_{MCA3} (refer to FIG. 9). Those contact electrodes CC5 that correspond to conductive layers 110 in the memory cell array layer L_{MCA2}, of the contact electrodes CC5 comprise the two tiered portions cc₂, cc₃ arranged in the Z-direction corresponding to the two memory cell array layers L_{MCA2}, L_{MCA3} (refer to FIG. 9). Those contact electrodes CC5 that correspond to conductive layers 110 in the memory cell array layer L_{MCA3}, of the contact electrodes CC5 comprise the tiered portion cc₃ corresponding to the memory cell array layer L_{MCA3} (refer to FIG. 9).

Moreover, the contact electrode CC5 comprises: a conductive member 551 extending in the Z-direction; an insulating column 552 which extends in the Z-direction, and has an outer peripheral surface covered by the conductive member 551; and the conductive member 153 which is provided in an upper end portion of the contact electrode CC5, has an outer peripheral surface contacting the conductive member 551, and has an upper surface contacting the contact electrode Ch.

A lower end of the conductive member 551 contacts the conductive layer 110. The conductive member 551 extends in the Z-direction penetrating the insulating layer 102. As shown in FIG. 63, for example, the conductive member 551 comprises: a barrier conductive film 554 extending in the Z-direction; and a metal film 555 which extends in the Z-direction, has an outer peripheral surface and lower end portion covered by the barrier conductive film 554, and contacts the barrier conductive film 554. The barrier conductive film 554 may include the likes of titanium nitride (TiN) or tantalum nitride (TaN), for example. The metal film 555 may include the likes of tungsten (W), molybdenum (Mo), or ruthenium (Ru), for example. The barrier conductive film 554 and metal film 555 are each formed in a substantially cylindrical shape.

The insulating column 552 may include the likes of silicon oxide (SiO₂), for example. An upper end portion of the insulating column 552 is covered by the conductive member 153, and contacts the conductive member 153 (more specifically, the barrier conductive film 156). A lower end portion and an outer peripheral surface of the insulating column 552 are covered by the conductive member 551, and contact the conductive member 551 (more specifically, the metal film 555). The insulating column 552 is formed in a substantially circular column-like shape.

Now, though illustration of the following is omitted, a part of the contact electrodes CC5 comprise the three tiered portions cc₁, cc₂, cc₃ arranged in the Z-direction (refer to FIG. 9), similarly to the contact electrode CC according to the first embodiment. Such contact electrodes CC5 may have voids formed inside their tiered portions cc₁, cc₂. Moreover, some others of the contact electrodes CC5 comprise the two tiered portions cc₂, cc₃ arranged in the Z-direction (refer to FIG. 9). Such contact electrodes CC5 may have a void formed inside their tiered portion cc₂.

Hence, in the contact electrode CC5 that contacts the conductive layer 110 at the contact electrode CC5's lower end, too, it is possible for remaining of fluorine gas to be suitably suppressed, due to the insulating column 552 being formed inside the conductive member 551. It is therefore possible for lowering of insulation between two conductive layers 110 arranged in the Z-direction to be suitably suppressed.

Moreover, it is possible for the contact electrode Ch and contact electrode CC5 to be suitably connected, due to the conductive member 153 being formed on the upper portion of the insulating column 552.

Moreover, it is possible for a low resistance contact electrode CC5 to be formed, due to the outer peripheral surface of the conductive member 153 contacting the inner peripheral surface of the conductive member 551.

Note that the conductive member 551 may further comprise the barrier conductive film 254 described with reference to FIG. 60. Moreover, the contact electrode CC5, similarly to the insulating column 352 described with reference to FIG. 61, may comprise: a barrier insulating film of the likes of silicon nitride (SiN) extending in the Z-direction; and an insulating film of the likes of silicon oxide (SiO₂) which extends in the Z-direction, and has an outer peripheral surface and a lower end portion covered by this barrier insulating film.

### Sixth Embodiment

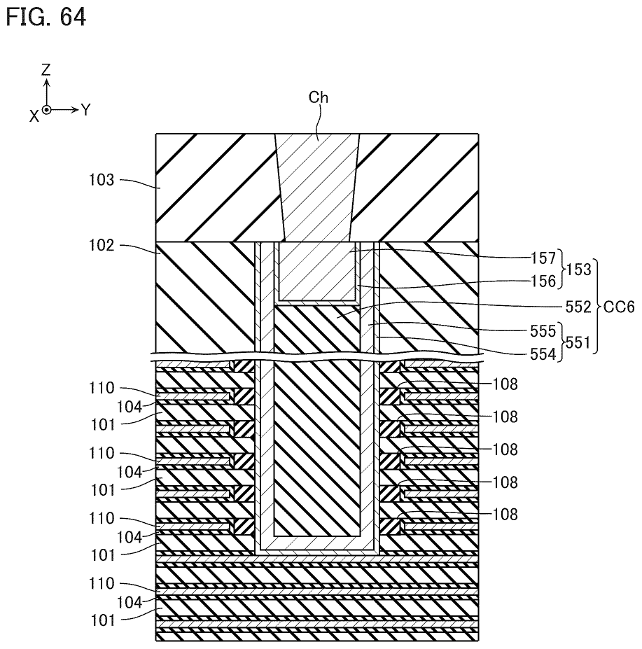

FIG. 64 is a schematic cross-sectional view of a semiconductor memory device according to a sixth embodiment. In the following description, configurations similar to in the fifth embodiment will be assigned with the same symbols as in the fifth embodiment, and descriptions thereof omitted.

The semiconductor memory device according to the sixth embodiment is basically configured similarly to the semiconductor memory device according to the fifth embodiment. However, the semiconductor memory device according to the sixth embodiment comprises the contact electrode CC6 instead of the contact electrode CC5.

The contact electrode CC6 is basically configured similarly to the contact electrode CC5. However, an outer peripheral surface of the contact electrode CC6 is surrounded by a through-hole provided in all of the conductive layers 110 other than the conductive layers 110(SGD), 110(SGDT), provided above said contact electrode CC6's corresponding conductive layer 110. Moreover, the outer peripheral surface of the contact electrode CC6 is provided with a plurality of the insulating layers 108 arranged in the Z-direction corresponding to the plurality of conductive layers 110. The conductive member 551 according to the present embodiment is insulated from the plurality of conductive layers 110 surrounding the contact electrode CC6 via these plurality of insulating layers 108.

In the contact electrode CC6 of the kind exemplified in the present embodiment, too, it is possible for remaining of fluorine gas to be suitably suppressed, due to the insulating column 552 being formed inside the conductive member 551. It is therefore possible for lowering of insulation between two conductive layers 110 arranged in the Z-direction to be suitably suppressed.

Moreover, it is possible for the contact electrode Ch and contact electrode CC6 to be suitably connected, due to the conductive member 153 being formed on the upper portion of the insulating column 552.

Moreover, it is possible for a low resistance contact electrode CC6 to be formed, due to the outer peripheral surface of the conductive member 153 contacting the inner peripheral surface of the conductive member 551. Note that the contact electrode CC6, similarly to the insulating column 352 described with reference to FIG. 61, may comprise: a barrier insulating film of the likes of silicon nitride (SiN) extending in the Z-direction; and an insulating film of the likes of silicon oxide (SiO₂) which extends in the Z-direction, and has an outer peripheral surface and a lower end portion covered by this barrier insulating film.

### Other Embodiments

That concludes description of the semiconductor memory devices according to the first through sixth embodiments. However, these configurations are merely exemplifications, and specific configurations may be appropriately adjusted.

For example, as described with reference to FIG. 9, the contact electrode CC according to the first embodiment comprises three tiered portions cc₁, cc₂, cc₃ arranged in the Z-direction corresponding to three memory cell array layers L_{MCA1}, L_{MCA2}, L_{MCA3}. The same applies also to the second through sixth embodiments. However, the contact electrode may comprise one or two tiered portions, or may comprise four or more tiered portions.

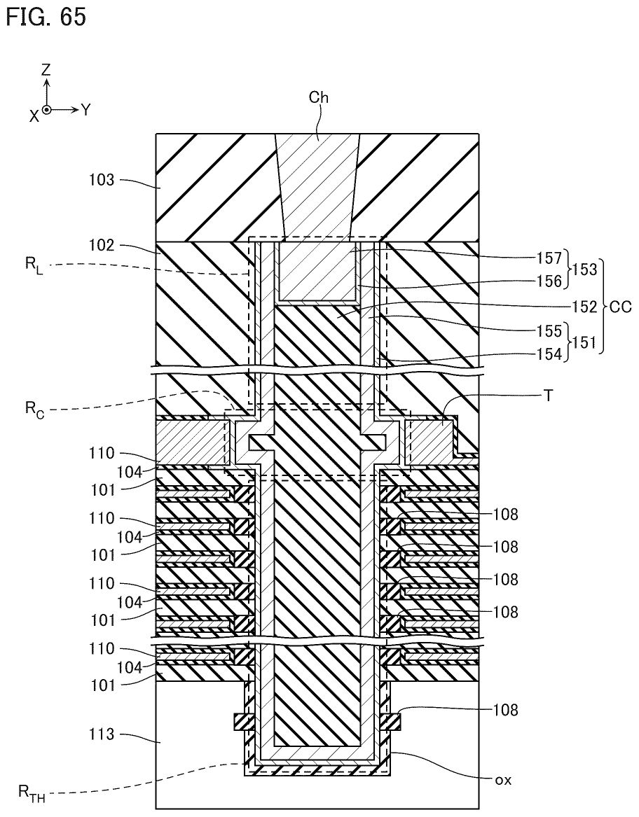

Moreover, in the first embodiment, for example, the sacrifice layer 113C formed in the step described with reference to FIG. 11 includes silicon. However, the sacrifice layer 113C may include silicon nitride. Moreover, the via holes HRA, the contact holes CCA, and the trenches STA formed in the step described with reference to FIG. 12 have their lower ends reaching the semiconductor layer 113E. However, these via holes HRA, contact holes CCA, and trenches STA may have their lower ends reaching the semiconductor layer 113A. FIG. 65 is a schematic cross-sectional view of a semiconductor memory device according to another embodiment, and shows a structure manufactured adopting such a method. When such a method is adopted, as shown in FIG. 65, for example, it results in an insulating layer 108 being provided on the outer peripheral surface of the conductive member 151 at a position below the upper surface of the conductive layer 113, but above the lower end of the contact electrode CC, too. The semiconductor memory devices according to the first through fourth embodiments may comprise such a configuration.

### [Others]

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a plurality of conductive layers stacked in a stacking direction;
a plurality of memory cells which are arranged in the stacking direction and are connected to the plurality of conductive layers;
a first contact electrode which extends in the stacking direction and is connected to one of the plurality of conductive layers; and
a second contact electrode which extends in the stacking direction and is connected to an end portion in the stacking direction of the first contact electrode, wherein
the first contact electrode comprises:
a first conductive member extending in the stacking direction;
an insulating column which extends in the stacking direction and has an outer peripheral surface covered by the first conductive member; and
a second conductive member which is provided in the end portion on a second contact electrode side in the stacking direction of the first contact electrode, has an outer peripheral surface contacting the first conductive member, and has a surface on the second contact electrode side in the stacking direction contacting the second contact electrode.

2. The semiconductor memory device according to claim 1, wherein
an end portion on the second contact electrode side in the stacking direction of the insulating column is covered by the second conductive member, and
an end portion on an opposite side to the second contact electrode in the stacking direction of the insulating column is covered by the first conductive member.

3. The semiconductor memory device according to claim 1, wherein
the first contact electrode comprises:
a first region which is provided at a position in the stacking direction corresponding to the one of the plurality of conductive layers, and contacts the one of the plurality of conductive layers;
a second region which is provided on the second contact electrode side in the stacking direction with respect to the first region, and extends in the stacking direction; and
a third region which is provided on an opposite side to the second contact electrode in the stacking direction with respect to the first region, and extends in the stacking direction, and
a width in a first direction intersecting the stacking direction, of the first region is greater than a width in the first direction of the second region and a width in the first direction of the third region.

4. The semiconductor memory device according to claim 3, wherein
an outer peripheral surface of the first region contacts the one of the plurality of conductive layers.

5. The semiconductor memory device according to claim 3, wherein
a surface on the opposite side to the second contact electrode in the stacking direction of the first region contacts the one of the plurality of conductive layers.

6. The semiconductor memory device according to claim 3, wherein
the one of the plurality of conductive layers comprises a terrace portion which is provided at a position corresponding to the first contact electrode, and
an outer peripheral surface of the first region contacts the terrace portion.

7. The semiconductor memory device according to claim 6, wherein
a length in the stacking direction of the terrace portion is greater than a length in the stacking direction of a portion different from the terrace portion, of the one of the plurality of conductive layers.

8. The semiconductor memory device according to claim 3, wherein
the one of the plurality of conductive layers comprises a terrace portion which is provided at a position corresponding to the first contact electrode, and
a surface on the opposite side to the second contact electrode in the stacking direction of the first region contacts the terrace portion.

9. The semiconductor memory device according to claim 8, further comprising:
an insulating member contacting an outer peripheral surface of the first region, wherein
a length in the stacking direction of the insulating member is less than a length in the stacking direction of the first region of the first contact electrode, and greater than a length in the stacking direction of the one of the plurality of conductive layers.

10. The semiconductor memory device according to claim 9, further comprising:
a high-dielectric-constant insulating film provided on surfaces on one side and the other side in the stacking direction of the insulating member.

11. The semiconductor memory device according to claim 3, wherein
a width in the first direction of a portion provided in the first region of the insulating column is greater than a width in the first direction of a portion provided in the second region of the insulating column and a width in the first direction of a portion provided in the third region of the insulating column.

12. The semiconductor memory device according to claim 3, wherein
the plurality of conductive layers include:
a first conductive layer being the one of the plurality of conductive layers; and
a plurality of second conductive layers provided on the opposite side to the second contact electrode in the stacking direction with respect to the first conductive layer, and
an outer peripheral surface of the third region is surrounded by the plurality of second conductive layers.

13. The semiconductor memory device according to claim 12, wherein
a portion provided in the third region of the first conductive member extends in the stacking direction penetrating the plurality of second conductive layers.

14. The semiconductor memory device according to claim 13, wherein
a portion provided in the third region of the insulating column extends in the stacking direction penetrating the plurality of second conductive layers.

15. The semiconductor memory device according to claim 12, further comprising:
a plurality of insulating layers which are arranged in the stacking direction corresponding to the plurality of second conductive layers, and are provided between the plurality of second conductive layers and the third region, wherein
the first contact electrode is insulated from the plurality of second conductive layers via the plurality of insulating layers.

16. The semiconductor memory device according to claim 1, further comprising:
a semiconductor column which extends in the stacking direction and faces the plurality of conductive layers;
an electric charge accumulating film provided between the plurality of conductive layers and the semiconductor column;
another conductive layer connected to an end portion on an opposite side to the second contact electrode in the stacking direction of the semiconductor column; and
an oxide layer which is provided between the another conductive layer and the first contact electrode, and covers an end portion on the opposite side to the second contact electrode in the stacking direction of the first contact electrode, wherein
the first contact electrode is insulated from the another conductive layer via the oxide layer.

17. The semiconductor memory device according to claim 1, wherein
an end portion on an opposite side to the second contact electrode in the stacking direction of the first contact electrode contacts the one of the plurality of conductive layers.

18. The semiconductor memory device according to claim 17, wherein
the plurality of conductive layers include:
a first conductive layer being the one of the plurality of conductive layers; and
a plurality of third conductive layers provided on the second contact electrode side in the stacking direction with respect to the first conductive layer, and
an outer peripheral surface of the first contact electrode is surrounded by the plurality of third conductive layers.

19. The semiconductor memory device according to claim 1, wherein
the first contact electrode comprises a plurality of tiered portions that are arranged in the stacking direction and have shapes of their respective side surfaces formed discontinuously.

20. The semiconductor memory device according to claim 19, wherein
the first conductive member and the insulating column are continuous in the stacking direction over the plurality of tiered portions.
